(19) United States
(12) Patent Application Publication
(10) Pub. No.: US 2005/0205880 A1
(43) Pub. Date: Sep. 22, 2005

(54) Display device and electronic appliance

(76) Inventors: Aya Anzai, Tsukui (JP); Jun Koyama, Sagamihara (JP); Hajime Kimura, Atsugi (JP); Shunpei Yamazaki, Tokyo (JP); Yoshifumi Tanada, Atsugi (JP); Mitsuaki Osame, Atsugi (JP)

Correspondence Address: FISH & RICHARDSON P.C., P.O. BOX 1022, MINNEAPOLIS, MN, 55440-1022, US

(21) Appl. No.: 11/079,598

(22) Filed: Mar. 15, 2005

(30) Foreign Application Priority Data
Mar. 19, 2004 (JP) 2004-080739
Apr. 28, 2004 (JP) 2004-134759

(51) Int. Cl. H01L 27/15

(52) U.S. Cl. 257/83; 257/79

(57) ABSTRACT

A low power consumption display device and an electronic appliances are provided. The display device of the invention comprises a pixel region including a plurality of pixels, a source driver, a first gate driver, and a second gate driver. Each of the plurality of pixels includes a light emitting element, a first transistor for controlling a video signal input to the pixel, a second transistor for controlling emission/non-emission of the light emitting element.

This application is based on Japanese Patent Application Nos. 2004-080739 and 2004-134759 filed with Japan Patent Office on Mar. 19, 2004 and Apr. 28, 2004, respectively, the entire contents of which are hereby incorporated by reference.

### BACKGROUND OF THE INVENTION

1. Field of the Invention

The present invention relates to a display device comprising self-light emitting elements, a driving method thereof and an electronic appliance such as a television set. In addition, the invention relates to an element substrate where elements are formed over an insulating surface. Further, the invention relates to a source driver and a gate driver each comprising a plurality of elements.

2. Description of the Related Art

In recent years, display devices comprising light emitting elements represented by EL (Electro Luminescence) elements have been developed, and wide applications thereof are expected by utilizing their advantages such as high image quality, wide viewing angle, thin shape, light weight of the self-luminous type. A light emitting element has a property that its luminance is proportional to a current value therein. In order to display gray scales accurately, there has been a display device where a constant current drive is adopted to flow a constant current to the light emitting element (see Patent Document 1).

[Patent Document 1] Japanese Patent Laid-Open No. 2003-323159.

Electronic appliances having a display function such as an information terminal and a portable phone have been widely spread, however, as such electronic appliances utilize batteries, reduction in power consumption is the key. However, when a constant current drive is adopted as in the display device disclosed in Patent Document 1, a driving transistor connected in series to a light emitting element has to be operated in the saturation region. Therefore, a high drive voltage is required which hinders the reduction in power consumption.

### SUMMARY OF THE INVENTION

In view of the foregoing, the invention provides a low power consumption display device and a driving method thereof.

A display device in accordance with one aspect of the present invention comprises a pixel region including a plurality of pixels, a source driver, a first gate driver and a second driver. Each of the plurality of pixels includes a light emitting element, a first transistor for controlling a video signal input to the pixel, a second transistor for controlling emission/non-emission of the light emitting element, and preferably a capacitor for storing a video signal.

The gate electrode of the first transistor is connected to the first gate driver and the second gate driver through a gate line. One of the source electrode and the drain electrode of the first transistor is connected to the source driver through a source line. The other of the source electrode and the drain electrode of the first transistor is connected to the gate electrode of the second transistor. One of the source electrode and the drain electrode of the second transistor is connected to a pixel electrode of the light emitting element. The other of the source electrode and the drain electrode of the second transistor is connected to a power source.

In the above configuration, only two transistors are disposed in each pixel, therefore, a high aperture ratio can be achieved. When a high aperture ratio is achieved, luminance of light emitting elements can be decreased in accordance with the increase in light emitting areas. Thus, a drive voltage of the light emitting elements can be decreased to reduce power consumption.

The display device of the invention adopts a constant voltage drive where a constant voltage is applied to a light emitting element. According to the constant voltage drive, a driving transistor is not required to be operated in the saturation region, and a drive voltage is not required to be increased. Therefore, power consumption can be lowered as compared to a constant current drive.

The capacitor may include a semiconductor layer provided in the same layer as the semiconductor layers of the first transistor and the second transistor, a conductive layer provided in the same layer as the gate electrodes of the first transistor and the second transistor, and an insulating layer provided between the semiconductor layer and the conductive layer. Alternatively, the capacitor may include a first conductive layer provided in the same layer as the gate electrodes of the first transistor and the second transistor, a second conductive layer provided in the same-layer as a conductive layer (source/drain wiring) connected to the source electrodes and the drain electrodes of the first transistor and the second transistor, and an insulating layer provided between the first conductive layer and the second conductive layer.

According to the invention having the above structure, the capacitor is provided below the source/drain wiring, therefore, an area of one pixel can be utilized effectively. Thus, the layout of the capacitor does not decrease the aperture ratio.

The conductive layer (source/drain wiring) connected to the source electrodes and the drain electrodes of the first transistor and the second transistor has a thickness of 500 to 1300 nm. In addition, a first insulating layer and a second insulating layer in contact with the first insulating layer are provided over the first transistor and the second transistor, and a first electrode of the light emitting element is provided on the second insulating layer.

A partition wall layer (insulating layer) is provided covering the edge of the first electrode of the light emitting element. The bank layer (insulating layer, also called as a bank layer in this specification) located above the capacitor has a width of 10 to 25 μm in the column direction. Alternatively, a bank layer (insulating layer) is provided covering the edge of the first electrode of the light emitting element, and the bank layer (insulating layer) transmits light.

One of the first electrode and the second electrode of the light emitting element reflects light while the other transmits light. Alternatively, both of the first electrode and the second electrode of the light emitting element transmit light.

The display device of the invention may include a power source control circuit for changing electric potentials of the first power source and the second power source so that a reverse bias can be applied to the light emitting element.

The display device of the invention may include a monitoring circuit that is operable in accordance with the ambient temperature, and a power source control circuit for changing an electric potential of a power source to be supplied to the pixel region based on the output of the monitoring circuit. The monitoring circuit includes a monitoring light emitting element.

The source driver included in the light emitting device of the invention includes a pulse output circuit, a latch, a selection circuit, a first protection circuit connected to an input node of the pulse output circuit, a second protection circuit provided between the pulse output circuit and the latch, and a third protection circuit provided between the selection circuit and the pixel region.

Each of the first gate driver and the second gate driver included in the display device of the invention includes a pulse output circuit, a selection circuit, a first protection circuit connected to an input node of the pulse output circuit, and a second protection circuit provided between the selection circuit and the pixel region.

The protection circuit includes one or more elements selected from a resistor, a capacitor and a rectifier. The rectifier is a transistor whose gate electrode and drain electrode are connected to each other, or a diode. The pulse output circuit corresponds to a plurality of flip-flop circuits or a decoder circuit.

The light emitting element may be formed of a material for red emission that is obtained from a triplet excitation state, a material for green emission that is obtained from a singlet excitation state, or a material for blue emission that is obtained from a singlet excitation state. Alternatively, the light emitting element is formed of a material for red emission that is obtained from a triplet excitation state, a material for green emission that is obtained from a triplet excitation state, or a material for blue emission that is obtained from a singlet excitation state. When using a material for emission obtained from the third excitation state, which exhibits high luminous efficiency, low power consumption can be achieved.

In the pixel region included in the display device of the invention, a plurality of power source lines connected to the first power source are provided along the columnar direction, and each power source line is shared by adjacent pixels.

The invention provides an element substrate that is in the condition where formation of up to the pixel electrode of the light emitting element has been completed in a display device having the above structure. More specifically, the element substrate corresponds to the condition where a transistor and a pixel electrode connected to the transistor have been formed on an insulating surface, but an electroluminescent layer and a counter electrode have not been yet formed.

The display device of the invention operates in the following manner. One frame period includes a plurality of sub-frame periods SF1, SF2, . . . , SFn (n is a natural number). Each of the sub-frame periods includes one of a plurality of writing periods Ta1, Ta2, . . . , Tan, and one of a plurality of light emitting periods Ts1, Ts2, . . . , Tsn. Each of the plurality of writing periods includes a plurality of gate selection periods. Each of the plurality of gate selection periods includes a plurality of sub-gate selection periods. For example, the length of the plurality of light emitting periods satisfies Ts1:Ts2: . . . :Tsn=2⁽ⁿ⁻¹⁾:2⁽ⁿ⁻²⁾: . . . :2⁰. The order of the plurality of light emitting periods may be random.

Alternatively, one or more periods selected from the plurality of sub-frame periods may be divided into a plurality of periods, in which case each of the one or more divided sub-frame periods, and each of the one or more undivided sub-frame periods includes one of a plurality of writing periods Ta1, Ta2, . . . , Tam (m is a natural number), and one of a plurality of light emitting periods Ts1, Ts2, . . . , Tsm. Each of the plurality of writing periods includes a plurality of gate selection periods, and each of the plurality of gate selection periods includes a plurality of sub-gate selection periods.

Alternatively, one or more periods selected from the sub-frame periods may be divided into a plurality of periods, in which case each of the one or more divided sub-frame periods, and each of the one or more undivided sub-frame periods includes one of a plurality of writing periods Ta1, Ta2 . . . , Tam (m is a natural number) and one of a plurality of light emitting periods Ts1, Ts2 . . . , Tsm. Each of the plurality of writing periods includes a plurality of gate selection periods, and each of the gate selection periods includes a plurality of sub-gate selection periods. The order of the plurality of light emitting periods is random.

In one period selected from the plurality of sub-gate selection periods, a gate line is selected by one of the first gate driver and the second gate driver while in another period selected from the plurality of sub-gate selection periods, a gate line is selected by the other of the first gate driver and the second gate driver. The light emitting element emits light or no light according to a video signal inputted to the gate electrode of the second transistor.

A transistor applicable to the invention is not limited to a certain type. It may be a thin film transistor (TFT) using a non-single crystalline semiconductor film represented by amorphous silicon or polycrystalline silicon, a MOS transistor formed by using a semiconductor substrate or an SOI substrate, a junction transistor, a bipolar transistor, a transistor using an organic semiconductor, a carbon nanotube or the like. In addition, a substrate over which transistors are formed is not limited to a certain type, and it may be a single crystalline substrate, an SOI substrate or a glass substrate.

In the invention, “connection” includes an “electrical connection”. Therefore, in the structure of the invention, other elements (for example, other elements or switches) that enable electrical connection may be provided in addition to a predetermined connection. Further, a capacitor disposed in a pixel may be replaced with a gate capacitance of a transistor and the like. In such a case, the capacitor may be omitted.

In addition, a switch may be any switch such as an electrical switch and a mechanical switch. It may be a transistor, a diode, or a logic circuit including them. Therefore, when using a transistor as a switch, the transistor operates just as a switch, thus a polarity (conductivity) of the transistor is not limited. However, when off-current is desirably small, a transistor of a polarity having smaller off-current is desirably employed. As a transistor having small off-current, there is the one provided with an LDD region. It is desirable that an N-channel transistor be employed when a transistor used as a switch operates with its source potential being closer to the low-potential-side power source (VSS, Vgnd, 0V and the like) while a P-channel transistor be employed when the transistor operates with its source potential being closer to the high-potential-side power source (VDD and the like). This is because an absolute value of the gate-source voltage can be increased which helps the operation of the switch. Note that a CMOS switch may be employed by using both N-channel and P-channel transistors.

According to the invention utilizing a constant voltage drive, a drive voltage of a light emitting element can be decreased to reduce power consumption as compared to the case of utilizing a constant current drive.

### BRIEF DESCRIPTION OF THE DRAWINGS

FIGS. 1A and 1B are diagrams illustrating a pixel included in the display device of the invention and its cross-sectional structure respectively.

FIG. 2 is a diagram illustrating a mask layout of pixels included in the display device of the invention.

FIG. 3 is a diagram illustrating a mask layout of pixels included in the display device of the invention.

FIG. 4 is a diagram illustrating a configuration of the display device of the invention.

FIG. 5 is a diagram illustrating a configuration of a source driver included in the display device of the invention.

FIG. 6 is a diagram illustrating a configuration of a source driver included in the display device of the invention.

FIG. 7 is a diagram illustrating a configuration of a source driver included in the display device of the invention.

FIG. 8 is a diagram illustrating a configuration of a gate driver included in the display device of the invention.

FIG. 9 is a diagram illustrating a configuration of a gate driver included in the display device of the invention.

FIG. 10 is a diagram illustrating the temperature compensation function of the invention.

FIGS. 11A and 11B are charts illustrating operation of the display device of the invention.

FIGS. 12A to 12D are charts illustrating a time gray scale method.

FIG. 13 is a chart illustrating a time gray scale method.

FIGS. 14A and 14B are diagrams illustrating a mask layout of pixels included in the display device of the invention, and a configuration thereof respectively.

FIGS. 15A and 15B are diagrams illustrating a panel according to a mode of the display device of the invention and its cross-sectional structure respectively.

FIGS. 16A and 16B are diagrams illustrating cross-sectional structures of a panel according to a mode of the display device of the invention.

FIGS. 17A to 17F are views illustrating electronic appliances each having the display device of the invention.

FIG. 18 is a diagram illustrating a configuration of a protection circuit.

FIGS. 19A and 19B are diagrams illustrating pixels included in the display device of the invention, and FIG. 19C is a diagram illustrating a cross-sectional structure thereof.

FIG. 20 is a diagram illustrating the compensation circuit of the invention.

FIGS. 21A and 21B are charts illustrating the temperature characteristics of a light emitting element.

FIG. 22 is a diagram illustrating the compensation circuit of the invention.

FIG. 23 is a diagram illustrating the compensation circuit of the invention.

FIG. 24 is a diagram illustrating the compensation circuit of the invention.

FIG. 25 is an exemplary source driver applicable to the invention.

FIG. 26 is an exemplary source driver applicable to the invention.

FIG. 27 is an exemplary source driver applicable to the invention.

FIG. 28 is a diagram illustrating a configuration of a gate driver included in the display device of the invention.

FIG. 29 is a diagram illustrating a configuration of a gate driver included in the display device of the invention.

FIG. 30 is a schematic diagram illustrating the display device of the invention provided with a delay circuit.

FIG. 31 is an exemplary delay circuit applicable to the invention.

FIG. 32 is an exemplary delay circuit applicable to the invention.

FIG. 33 is an exemplary delay circuit applicable to the invention.

FIG. 34 is a timing chart of a delay circuit applicable to the invention.

FIG. 35 is a timing chart of a delay circuit applicable to the invention.

FIG. 36 is a diagram illustrating a configuration of the display device of the invention.

### DETAILED DESCRIPTION OF THE INVENTION

Although the invention will be fully described by way of embodiment modes and embodiments with reference to the accompanying drawings, it is to be understood that various changes and modifications will be apparent to those skilled in the art. Therefore, unless otherwise such changes and modifications depart from the scope of the invention, they should be constructed as being included therein. Note that in the structure of the invention hereinafter described, identical portions are denoted by identical reference numerals among all the drawings.

### Embodiment Mode 1

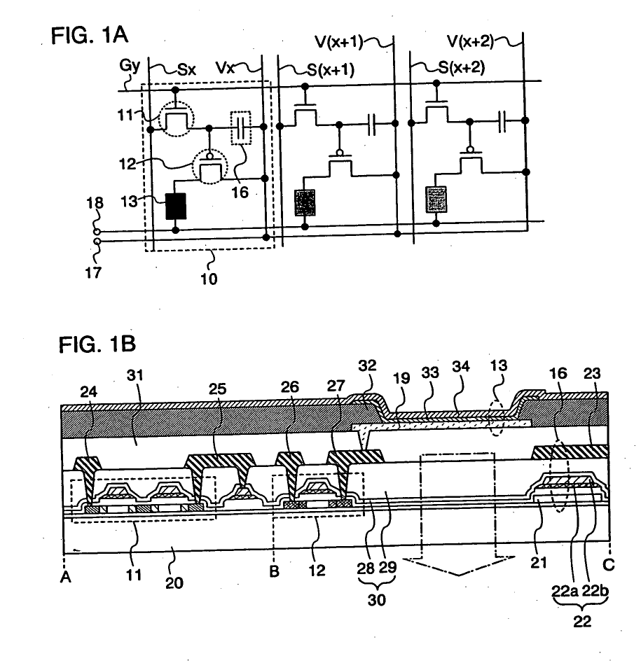

The structure of a display device in accordance with a preferred embodiment of the invention is described below with reference to FIGS. 1A to 3. The display device of the invention comprises a plurality of pixels 10 each including a plurality of elements in the region where a source line Sx (x is a natural number, and 1≦x≦m is satisfied) and a gate line Gy (y is a natural number, and 1≦y≦n is satisfied) cross each other with an insulator interposed therebetween (see FIG. 1A). The pixel 10 includes a light emitting element 13, a capacitor 16 and two transistors. One of the two transistors is a switching transistor 11 (hereinafter also referred to as a TFT 11) for controlling a video signal input to the pixel 10 and a driving transistor 12 (hereinafter also referred to as a TFT 12) for controlling emission/non-emission of the light emitting element 13. Each of the TFTs 11 and 12 is a field effect transistor that has three terminals of a gate electrode, a source electrode and a drain electrode.

The gate electrode of the TFT 11 is connected to a gate line Gy, and one of the source electrode and the drain electrode thereof is connected to a source line Sx while the other thereof is connected to the gate electrode of the TFT 12. One of the source electrode and the drain electrode of the TFT 12 is connected to a first power source 17 through a power source line Vx (x is a natural number, and 1≦x≦m is satisfied) while the other thereof is connected to a pixel electrode of the light emitting element 13. A counter electrode of the light emitting element 13 is connected to a second power source 18. The capacitor 16 is disposed between the gate electrode and the source electrode of the TFT 12. The conductivity of the TFTs 11 and 12 is not limited, and either of an N-channel TFT and a P-channel TFT may be employed. FIG. 1A illustrates the case where the TFT 11 is an N-channel TFT and the TFT 12 is a P-channel TFT. Potentials of the first power source 17 and the second power source 18 are not limited. However, they are only required to be set at different potentials so that a forward bias voltage or a reverse bias voltage is applied to the light emitting element 13.

In the display device of the invention having the above configuration, only two transistors are disposed in the pixel 10. Accordingly, the number of transistors disposed in one pixel 10 can be decreased, which inevitably reduces the number of wirings necessary. Thus, a high aperture ratio, high resolution and a high yield can be achieved. When a high aperture ratio is achieved, luminance of light emitting elements can be decreased in accordance with the increase in light emitting areas. That is, a current density can be decreased. Thus, a drive voltage can be decreased to reduce power consumption. Further, the low drive voltage will improve the reliability.

Semiconductors constituting the TFTs 11 and 12 may be any of an amorphous semiconductor (amorphous silicon), a micro-crystalline semiconductor, a polycrystalline semiconductor (polysilicon) and an organic semiconductor. The micro-crystalline semiconductor may be formed by using a silane gas (SiH₄) and a fluorine gas (F₂) or using a silane gas and a hydrogen gas. Alternatively, it may be obtained by forming a thin film using the above gas and subsequently irradiating it with laser light. Each of the gate electrodes of the TFTs 11 and 12 is formed to have a single or a plurality of layers utilizing a conductive material.

For example, a stacked-layer structure of tungsten (W) and tungsten nitride (WN), a stacked-layer structure of molybdenum (Mo), aluminum (Al) and molybdenum (Mo) or a stacked-layer structure of molybdenum (Mo) and molybdenum nitride (MoN) may be employed.

A conductive layer (source/drain wiring) connected to impurity regions (source electrode and drain electrode) included in the TFTs 11 and 12 is formed with a single layer or a plurality of layers utilizing a conductive material. For example, a stacked layer of titanium (Ti), aluminum-silicon (Al—Si) and titanium (Ti), a stacked layer of molybdenum (Mo), aluminum-silicon (Al—Si) and molybdenum (MO) or a stacked layer of molybdenum nitride (MoN), aluminum-silicon (Al—Si) and molybdenum nitride (MoN) may be employed.

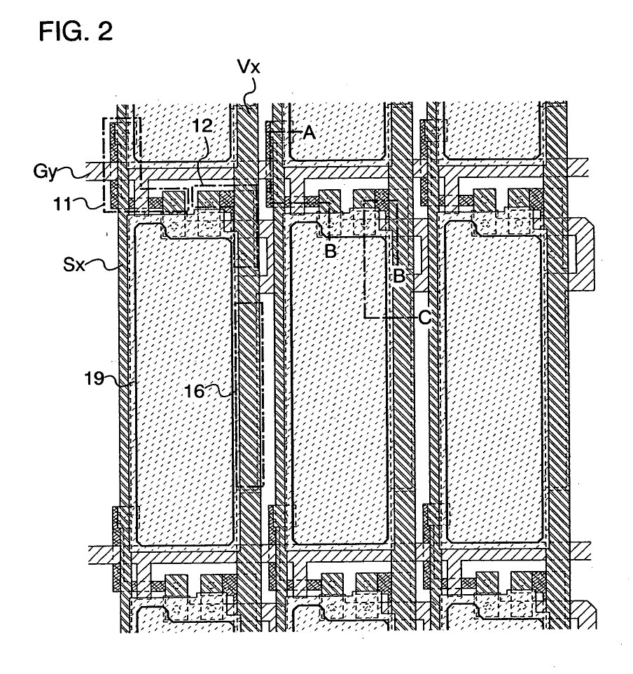

FIG. 2 illustrates a layout of the pixels 10 having the above configuration. Shown in this layout are the TFTs 11 and 12, the capacitor 16, a conductive layer 19 that corresponds to the pixel electrode of the light emitting element 13. FIG. 1B illustrates a cross-sectional structure of the layout in FIG. 2 along a line A-B-C. The TFTs 11 and 12, the light emitting element 13 and the capacitor 16 are formed over a substrate 20 having an insulating surface such as glass and quartz.

The light emitting element 13 corresponds to stacked layers of the conductive layer 19 (pixel electrode), an electroluminescent layer 33 and a conductive layer 34 (counter electrode). When both of the conductive layers 19 and 34 transmit light, the light emitting element 13 emits light in both directions of the conductive layer 19 and the conductive layer 34. That is, the light emitting element 13 emits light to both sides. On the other hand, when one of the conductive layers 19 and 34 transmits light while the other shields light, the light emitting element 13 emits light only in the direction of the conductive layer 19 or the conductive layer 34. That is, the light emitting element 13 emits light to the top side or the bottom side. FIG. 1B illustrates a cross-sectional structure in the case where the light emitting element 13 emits light to the bottom side.

The capacitor 16 is disposed between the gate electrode and the source electrode of the TFT 12 and stores a gate-source voltage of the TFT 12. The capacitor 16 forms a capacitance by a semiconductor layer 21 provided in the same layer as the semiconductor layers included in the TFTs 11 and 12, conductive layers 22a and 22b (hereinafter collectively referred to as a conductive layer 22) provided in the same layer as the gate electrodes of the TFTs 11 and 12, and an insulating layer provided between the semiconductor layer 21 and the conductive layer 22. Also, the capacitor 16 forms a capacitance by the conductive layer 22 provided in the same layer as the gate electrodes of the TFTs 11 and 12, a conductive layer 23 provided in the same layer as conductive layers 24 to 27 that are connected to the source electrode or the drain electrode of the TFTs 11 and 12, and an insulating layer provided between the conductive layer 22 and the conductive layer 23. According to such a structure, the capacitor 16 can have a capacitance value large enough to store the gate-source voltage of the TFT 12. In addition, the capacitor 16 is provided below the conductive layer constituting a power source line, therefore, the layout of the capacitor 16 does not decrease the aperture ratio.

The conductive layers 24 to 27 each corresponding to the source/drain wiring of the TFTs 11 and 12 and the conductive layer 23 are 500 to 2000 nm thick, or more preferably 500 to 1300 nm thick. The conductive layers 23 to 27 constitute the source line Sx and the power source line Vx. Therefore, by forming the conductive layers 23 to 27 thick as set forth above, an effect of a voltage drop can be suppressed. Note that when forming the conductive layers 23 to 27 thick, wiring resistance can be made small. However, when forming the conductive layers 23 to 27 extremely thick, it becomes difficult to perform a patterning process accurately or the surface will have more irregularity. That is, the thickness of the conductive layers 23 to 27 is desirably controlled within the above range in consideration of the wiring resistance, the patterning process to be performed easily and irregularity of the surface.

In addition, insulating layers 28 and 29 (hereinafter collectively referred to as a first insulating layer 30) covering the TFTs 11 and 12, a second insulating layer 31 provided on the first insulating layer 30, and the conductive layer 19 corresponding to the pixel electrode that is formed on the second insulating layer 31 are provided. The provision of the second insulating layer 31 increases a margin of the region where the conductive layer 19 is formed, which achieves a high aperture ratio. Such a structure is quite effective when adopting a top emission structure. When a high aperture ratio is achieved, a drive voltage can be decreased in accordance with the increase in light emitting areas, which contributes to reduction in power consumption.

Note that the first insulating layer 30 and the second insulating layer 31 are formed by using an inorganic material such as silicon oxide and silicon nitride, an organic material such as polyimide and acrylic and the like. The first insulating layer 30 and the second insulating layer 31 may be formed by using either the same materials or different materials. Also, as one or both of these insulating layers 30 and 31, a siloxane material may be employed. The siloxane has a skeleton structure of Si—O—Si bond and containing as a substituent an organic group containing at least hydrogen (for example, alkyl group or aromatic hydrocarbon). A fluoro group may also be used as a substituent. Further, it is possible to use both the organic group containing hydrogen and the fluoro group.

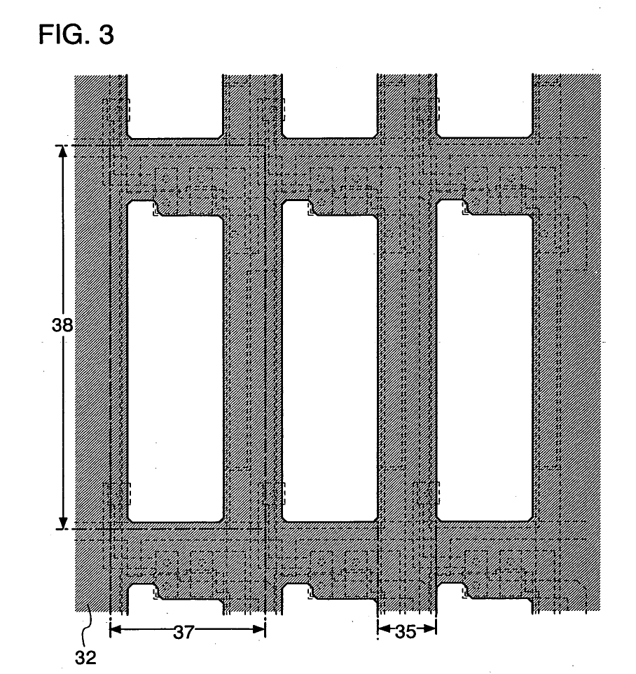

Between the light emitting elements 13, a bank layer 32 (also referred to as a bank, a partition or an insulating layer) is provided. A width 35 of the bank layer 32 over the capacitor 16 may be wide enough to cover the wirings provided on the bottom portion. Preferably, the width 35 is 7.5 to 27.5 μm, or more preferably 10 to 25 μm (see FIG. 3). In this manner, by forming the bank layer 32 narrow, a high aperture ratio can be achieved. When a high aperture ratio is achieved, a drive voltage can be decreased in accordance with the increase in light emitting areas, which contributes to reduction in power consumption.

Note that in the shown layout, an aperture ratio of the pixel is about 50%. The length of the pixel 10 in the column direction (longitudinal direction) is shown by a width 38 while the length of the pixel 10 in the row direction (lateral direction) is shown by a width 37. The bank layer 32 may be formed of either an inorganic material or an organic material. However, as the electroluminescent layer is provided so as to be in contact with the bank layer 32, the bank layer 32 is desirably formed to have a continuously variable curvature radius so as not to produce pin holes in the electroluminescent layer.

In addition, the bank layer 32 shields light. According to such a structure, borders of the adjacent pixels 10 become clearer, whereby a high resolution image can be displayed. The bank layer 32 contains a pigment or a carbon nanotube. Because of the additive of pigment or carbon, the bank layer 32 is colored to shield light.

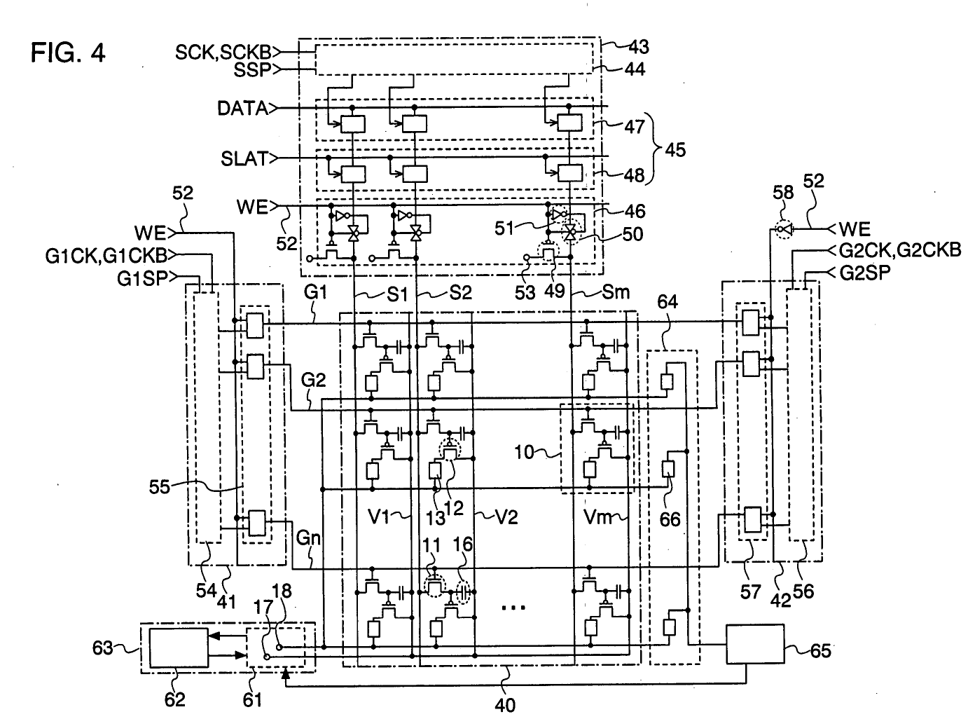

The display device of the invention comprises a pixel region 40 where a plurality of the aforementioned pixels 10 are arranged in a matrix, a first gate driver 41, a second gate driver 42 and a source driver 43 (see FIG. 4). The first gate driver 41 and the second gate driver 42 may be disposed on opposite sides of the pixel region 40 as shown in the figure or on one side of the pixel region 40.

The source driver 43 includes a pulse output circuit 44, a latch 45 and a selection circuit 46. The latch 45 includes a first latch 47 and a second latch 48. The selection circuit 46 includes a transistor 49 (hereinafter referred to as a TFT 49) and an analog switch 50. The TFT 49 and the analog switch 50 are disposed in each column correspondingly to the source line Sx. The inverter 51 generates an inverted signal of a WE (Write/Erase) signal, and it is not necessarily provided when the WE signal is supplied externally. The gate electrode of the TFT 49 is connected to a selection signal line 52, and one of the source electrode and the drain electrode thereof is connected to the source line Sx while the other is connected to a power source 53. The analog switch 50 is provided between the second latch 48 and the source line Sx. That is, an input node of the analog switch 50 is connected to the second latch 48 and an output node thereof is connected to the source line Sx. One of the two control nodes of the analog switch 50 is connected to the selection signal line 52 while the other is connected to the selection signal line 52 through the inverter 51. A potential of the power source 53 has a level to turn OFF the TFT 12 included in the pixel 10, and it is an L level when the TFT 12 is an N-channel TFT while it is an H level when the TFT 12 is a P-channel TFT.

The first gate driver 41 includes a pulse output circuit 54 and a selection circuit 55. The second gate driver 42 includes a pulse output circuit 56 and a selection circuit 57. The selection circuits 55 and 57 are connected to the selection signal line 52. Note that the selection circuit 57 included in the second gate driver 42 is connected to the selection signal line 52 through the inverter 58. That is, WE signals inputted to the selection circuits 55 and 57 through the selection signal line 52 are inverted from each other.

Each of the selection circuits 55 and 57 includes a tristate buffer. An input node of the tristate buffer is connected to the pulse output circuit 54 or the pulse output circuit 56 while a control node thereof is connected to the selection signal line 52. An output node of the tristate buffer is connected to the gate line Gy. The tristate buffer operates when a signal transmitted from the selection signal line 52 has an H level while it is in the floating state when a signal transmitted from the selection signal line 52 has an L level.

The pulse output circuit 44 included in the source driver 43, the pulse output circuit 54 included in the first gate driver 41 and the pulse output circuit 56 included in the second gate driver 42 correspond to a shift register having a plurality of flip-flop circuits, or a decoder circuit. When adopting a decoder circuit for each of the pulse output circuits 44, 54 and 56, the source line Sx or the gate line Gy can be selected at random. When the source line Sx or the gate line Gy can be selected at random, pseudo contours that occur when adopting a time gray scale method can be suppressed.

Note that the configuration of the source driver 43 is not limited to the above, and a level shifter and a buffer may be provided additionally. Note also that the configurations of the first gate driver 41 and the second gate driver 42 are not limited to the above, and a level shifter and a buffer may be provided additionally. Further, though not shown, each of the source driver 43, the first gate driver 41 and the second gate driver 42 includes a protection circuit. The configuration of the driver including a protection circuit is described in Embodiment Mode 2 below.

In addition, the display device of the invention includes a power source control circuit 63. The power source control circuit 63 includes a controller 62 and a power source circuit 61 for supplying power to the light emitting element 13. The power source circuit 61 is connected to the pixel electrode of the light emitting element 13 through the TFT 12 and the power source line Vx. Also, the power source circuit 61 is connected to the counter electrode of the light emitting element 13 through the power source line.

When a forward bias voltage is applied to the light emitting element 13 so as to supply a current to the light emitting element 13 to emit light, the first power source 17 and the second power source 18 are set to have a potential difference so that the potential of the first power source 17 is higher than the potential of the second power source 18. On the other hand, when a reverse bias voltage is applied to the light emitting element 13, the first power source 17 and the second power source 18 are set to have a potential difference so that the potential of the first power source 17 is lower than the potential of the second power source 18. Such potential setting is performed by supplying a predetermined signal from the controller 62 to the power source circuit 61.

According to the invention, a reverse bias voltage is applied to the light emitting element 13 using the power source control circuit 63, whereby degradation of the light emitting element 13 with the passage of time can be suppressed to improve the reliability. The light emitting element 13 may have an initial defect that the anode and the cathode thereof are short-circuited due to adhesion of foreign substances, pinholes that are produced by minute projections of the anode or the cathode, or irregularity of the electroluminescent layer. Such an initial defect will disturb emission/non-emission in accordance with signals, and a problem will arise where a favorable image display cannot be performed because the whole elements do not emit light with almost all currents flown to the short-circuit portion, or specific pixels emit light or no light. However, according to the structure of the invention, a reverse bias can be applied to the light emitting element, whereby a current can locally flow only to the short-circuit portion of the anode and the cathode so as to generate heat in the short-circuit portion. As a result, the short-circuit portion can be insulated by oxidizing or carbonizing. Thus, favorable image display can be performed even when an initial defect occurs by eliminating the defect. Note that insulation of such an initial defect is preferably carried out before shipment. Further, not only an initial defect, but another defect might occur where the anode and the cathode are short-circuited with the passage of time. Such a defect is called a progressive defect. However, according to the invention, a reverse bias can be applied to the light emitting element at regular intervals, therefore, such possible progressive defect can be eliminated and favorable image display can be performed. Note that the timing for applying a reverse bias voltage to the light emitting element 13 is not specifically limited.

The display device of the invention also includes a monitoring circuit 64 and a control circuit 65. The monitoring circuit 64 operates in accordance with the ambient temperature. The control circuit 65 includes a constant current source and a buffer. In the shown configuration, the monitoring circuit 64 includes a monitoring light emitting element 66 (hereinafter also referred to as light emitting element 66).

The control circuit 65 supplies a signal for changing a power source potential to the power source control circuit 63 based on the output of the monitoring circuit 64. The power source control circuit 63 changes a power source potential to be supplied to the pixel region 40 based on the signal supplied from the control circuit 65. According to the invention having the above configuration, fluctuations of a current value caused by changes in the ambient temperature can be suppressed to improve the reliability. Note that specific configurations of the monitoring circuit 64 and the control circuit 65 are described in Embodiment Mode 3 below.

According to the display device of the invention that performs a constant voltage drive, luminance of the light emitting elements is 500 cd/m², and power consumption is 1 W or less (950 mW) with the pixel aperture ratio of 50%. On the other hand, according to a display device that performs a constant current drive, luminance of the light emitting elements is 500 cd/m², and power consumption is 2 W (2040 mW) with the pixel aperture ratio of 25%. That is, by adopting a constant voltage drive, power consumption can be reduced. By adopting a constant voltage drive, power consumption can be suppressed to 1 W or less, or more preferably to 0.7 W or less. Note that the above value of the power consumption is only of the pixel region, and does not include the power consumption of the driver circuit portions. In addition, both exhibit a display duty ratio of 70% with the time gray scale method adopted.

In addition, the number of the pixels in the pixel region is 240×3×320 in both of the display device for performing a constant voltage drive and the display device for performing a constant current drive of which power consumption were measured as set forth above.

Note that as set forth above, transistors of the invention may be of any types, and may be formed over any substrate. Therefore, the whole circuit as shown in FIG. 4 may be formed over any kind of substrate such as a glass substrate, a plastic substrate, a single crystalline substrate and an SOI substrate. Alternatively, a part of the circuit in FIG. 4 may be formed over a certain substrate while another part thereof may be formed over another substrate. That is, not the whole circuit in FIG. 4 is required to be formed over the same substrate. For example, such structure may be employed in FIG. 4 that the pixel region 40 and the first gate driver 41 are formed over a glass substrate with TFTs while the source driver 43 (or a part of it) is formed over a single crystalline substrate, whereby the IC chip is connected onto the glass substrate by COG (Chip On Glass) bonding. Alternatively, the IC chip may be connected to the glass substrate by TAB (Tape Auto Bonding) or by using a printed board.

### Embodiment Mode 2

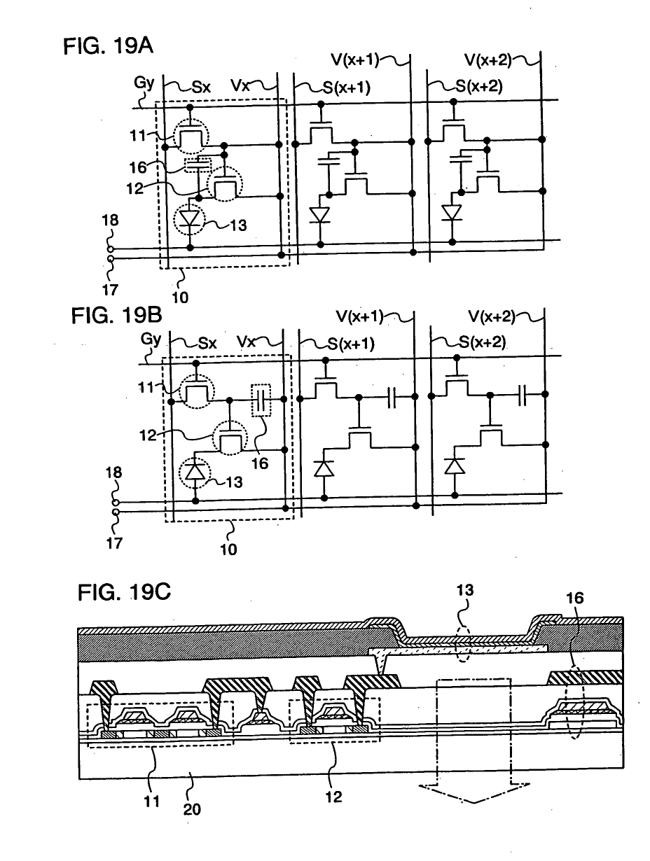

The aforementioned configuration employed the case where the TFT 12 is a P-channel TFT. In this embodiment mode, description is made with reference to FIGS. 19A to 19C on the case where the TFT 12 is an N-channel TFT. The pixel 10 includes the light emitting element 13, the capacitor 16 and the TFTs 11 and 12 (see FIG. 19A). When the light emitting element 13 has a forward stacking structure (when the pixel electrode is an anode while the counter electrode is a cathode), and a forward bias voltage is applied to the light emitting element 13 in accordance with the current flow direction of the light emitting element 13, the first power source 17 corresponds to a high potential power source while the second power source 18 corresponds to a low potential power source. When a reverse bias voltage is applied to the light emitting element 13, on the other hand, the first power source 17 is a low potential power source while the second power source 18 is a high potential power source. The capacitor 16 stores a gate-source voltage of the TFT 12. According to the above configuration, the source electrode of the TFT 12 is connected to the pixel electrode of the light emitting element 13, therefore, the capacitor 16 is disposed between the pixel electrode of the light emitting element 13 and the gate electrode of the TFT 12.

On the other hand, when the light emitting element 13 has an inversely stacked structure (when the pixel electrode is a cathode while the counter electrode is an anode), and a forward bias voltage is applied to the light emitting element 13 in accordance with the current flow direction of the light emitting element 13, the first power source 17 corresponds to a low potential power source while the second power source 18 corresponds to a high potential power source. When a reverse bias voltage is applied to the light emitting element 13, on the other hand, the first power source 17 is a high potential power source while the second power source 18 is a low potential power source. In addition, the source electrode of the TFT 12 is connected to the power source line Vx, therefore, the capacitor 16 is disposed between the power source line Vx and the gate electrode of the TFT 12.

FIG. 19C illustrates a cross-sectional structure of the display device shown in FIG. 19A. In the display device, the TFTs 11 and 12, the light emitting element 13 and the capacitor 16 are formed over the substrate having an insulating surface such as glass and quartz. The conductivity of the TFT 11 is not specifically limited, and when the TFT 11 is an N-channel TFT, the TFTs 11 and 12 have the same conductivity. And hence, the TFTs are not required to be formed separately, which improves the yield.

In the display device having the structure above, only two transistors are disposed in the pixel 10. Accordingly, a high aperture ratio, high resolution and a high yield can be achieved. When a high aperture ratio is achieved, a drive voltage can be decreased, which contributes to reduction in power consumption.

### Embodiment Mode 3

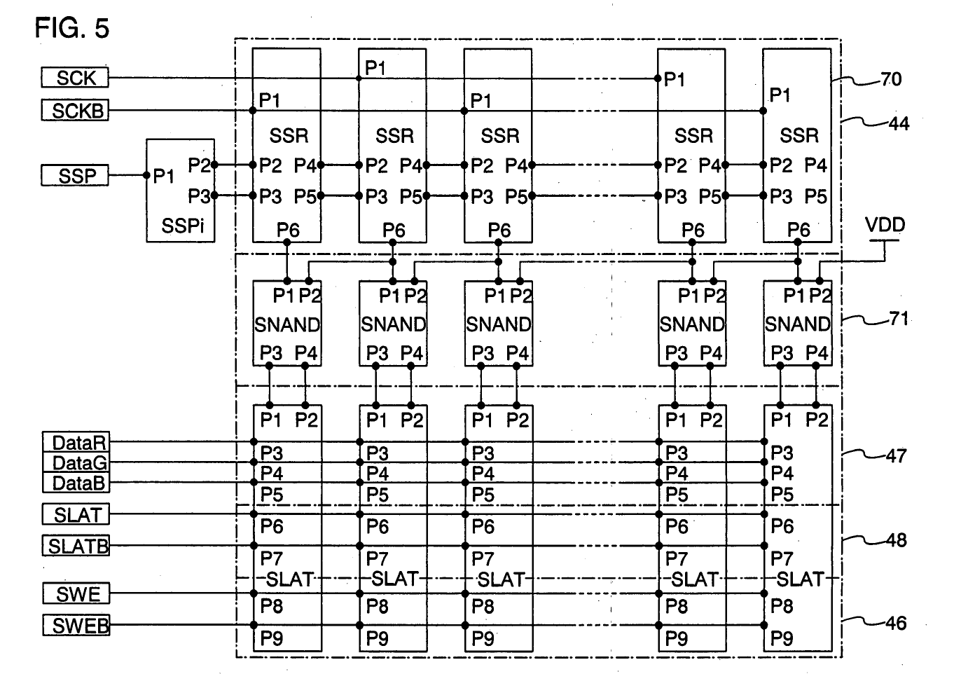

Description is made now with reference to FIGS. 5 to 7 on the configuration of the source driver 43 included in the display device of the invention. The source driver 43 includes the pulse output circuit 44, a NAND 71, the first latch 47, the second latch 48 and the selection circuit 46 (the first latch 47, the second latch 48 and the selection circuit 46 are collectively referred to as an SLAT in the drawing) (see FIG. 5). The pulse output circuit 44 has a configuration in which a plurality of unit circuits (SSR) 70 are connected in cascade. The pulse output circuit 44 is supplied with a clock signal (SCK), a clock back signal (SCKB) and a start pulse (SSP). The first latch 47 is supplied with data signals (DataR, DataG and DataB). The second latch 48 is supplied with a latch pulse (SLAT), and an inverted pulse of the latch pulse (SLATB). The selection circuit 46 is supplied with a writing/erasing signal (SWE or Write/Erase signal, hereinafter also referred to as a WE signal), and an inverted signal of the WE signal (SWEB).

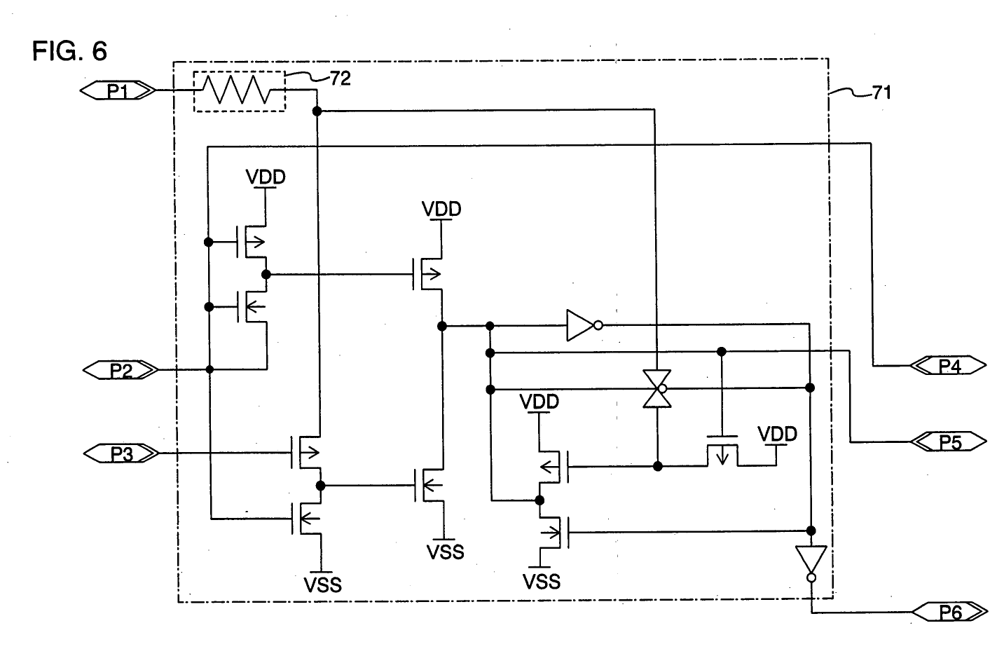

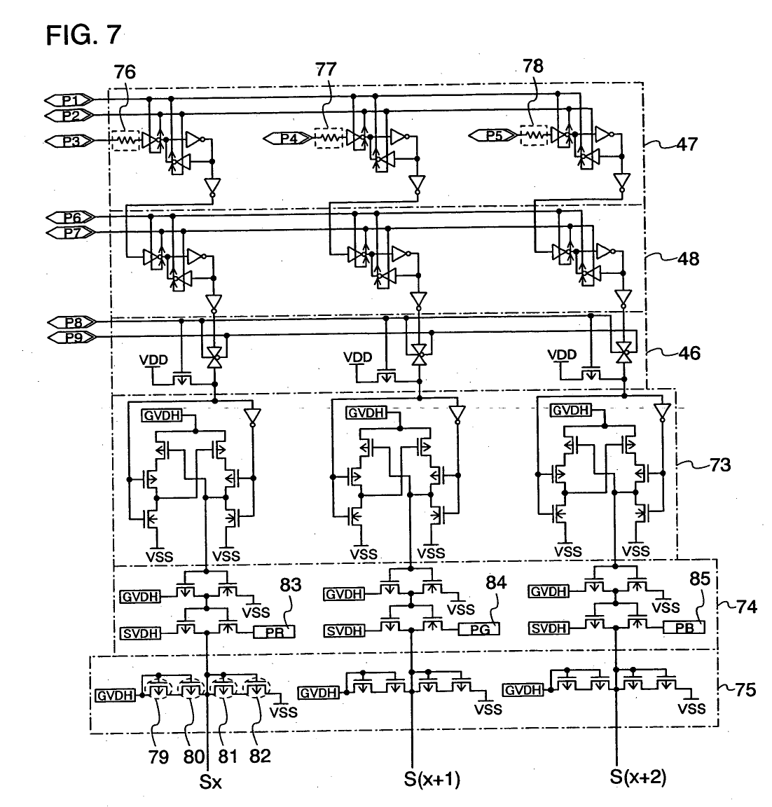

The unit circuit 70 included in the pulse output circuit 44 includes a plurality of transistors and logic circuits (see FIG. 6). An input node (P1) of the unit circuit 70, to which a clock signal or a clock back signal are supplied, is provided with a resistor 72 as a protection circuit. Also, input nodes of the first latch 47, to which data signals are inputted, are provided with resistors 76 to 78 as protection circuits respectively (see FIG. 7). Further, though not shown in FIG. 5, the lower stage of the selection circuit 46 is provided with a level shifter 73 and a buffer 74, and the lower stage of the buffer 74 is provided with a protection circuit 75. The protection circuit 75 includes four transistors 79 to 82 per source line. Note that power source potentials 83 to 85 supplied to the buffer 74 are set according to the color to be emitted from a pixel that is connected to the source line Sx.

The source driver 43 includes a first protection circuit (corresponds to the resistor 72 in the drawing) connected to the input node of the pulse output circuit 44, a second protection circuit (corresponds to the resistors 76 to 78 in the drawing) connected to the input nodes of the first latch 47, and a third protection circuit (corresponds to the transistors 79 to 82 in the drawing) provided on the lower stage of the selection circuit 46. According to such a configuration, degradation or breakdown of elements caused by static electricity can be suppressed.

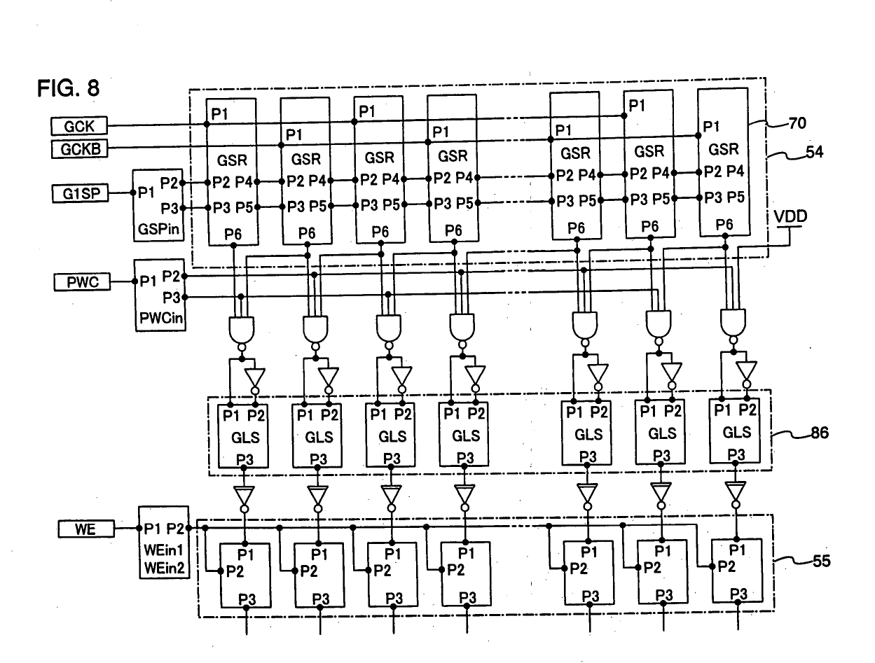

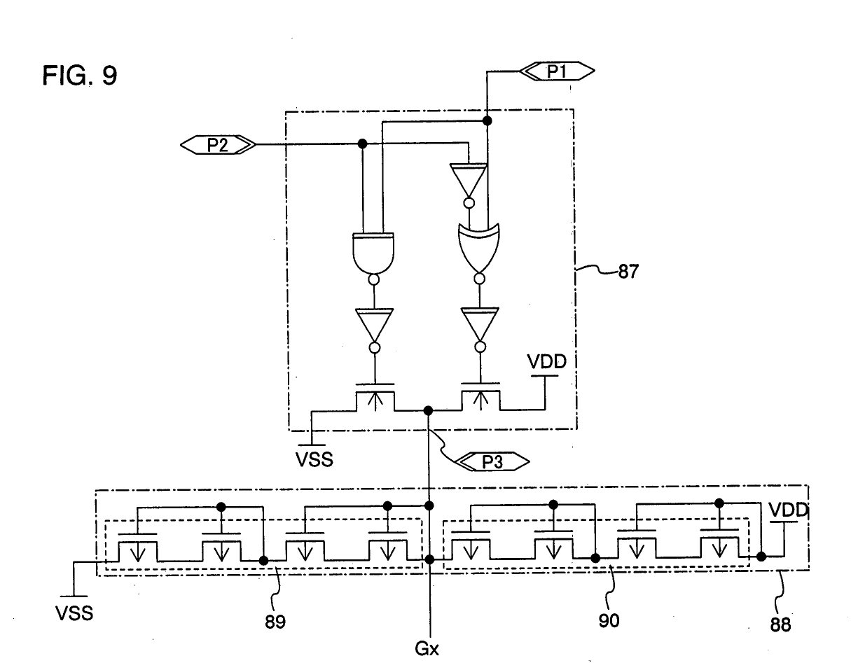

Description is made now with reference to FIGS. 8 and 9 on the configuration of the first gate driver 41. The second gate driver 42 has a similar configuration to the first gate driver 41, therefore, the description thereof is omitted herein. The first gate driver 41 includes the pulse output circuit 54, a level shifter (GLS) 86 and the selection circuit 55 (see FIG. 8). The configuration of the pulse output circuit 54 is similar to that of the pulse output circuit 44 included in the source driver 43, and it has a configuration where a plurality of the unit circuits (GSR) 70 are connected in cascade, and the input node thereof is provided with a protection circuit.

The selection circuit 55 includes a tristate buffer 87 and a protection circuit 88 (see FIG. 9). The tristate buffer 87 functions to prevent that when one of the first gate driver 41 and the second gate driver 42 charges or discharges the gate line Gy, the operation is disturbed by the output of the other drivel Accordingly, the selection circuit 55 may be an analog switch, a clocked inverter and the like in addition to the tristate buffer as long as the above function is provided. The protection circuit 88 includes element groups 89 and 90.

The first gate driver 41 includes the first protection circuit connected to the input node of the pulse output circuit 54 and the second protection circuit 88 provided on the lower stage of the protection circuit 55. According to such a configuration, degradation or breakdown of elements caused by static electricity can be suppressed. More specifically, there is a possibility that a clock signal or a data signal inputted to the input node has noise, which instantaneously applies a high voltage or a low voltage to elements. However, according to the invention having a protection circuit, malfunction, degradation or breakdown of elements can be suppressed.

Note that the protection circuit is constructed by using not only a resistor and a transistor, but one or more elements selected from a resistor, a capacitor and a rectifier. The rectifier is a transistor whose gate electrode and drain electrode are connected to each other, or a diode.

Description is made now on the operation of the protection circuit. Here, description is made on the operation of the protection circuit 88 included in the first gate driver 41. First, a signal of a higher voltage than VDD is supplied from the output node of the tristate buffer 87 due to an effect of noise and the like. Then, the element group 89 is turned OFF while the element group 90 is turned ON because of the relationship of their gate-source voltages. Then, a charge stored in the tristate buffer 87 is released to the power source line for transmitting VDD, thereby a potential of the gate line Gx becomes VDD or VDD+α. On the other hand, if a signal of a voltage lower than VSS is supplied from the output node of the tristate buffer 87, the element group 89 is turned ON while the element group 90 is turned OFF because of the relationship of their gate-source voltages. Then, the potential of the gate line Gx becomes VSS or VSS−α. In this manner, even when a voltage supplied from the output node of the tristate buffer 87 becomes higher than VDD or lower than VSS instantaneously due to noise and the like, the voltage supplied to the gate line Gx does not become higher than the VDD nor lower than VSS. Accordingly, malfunction, degradation or breakdown of elements caused by noise, static electricity and the like can be suppressed.

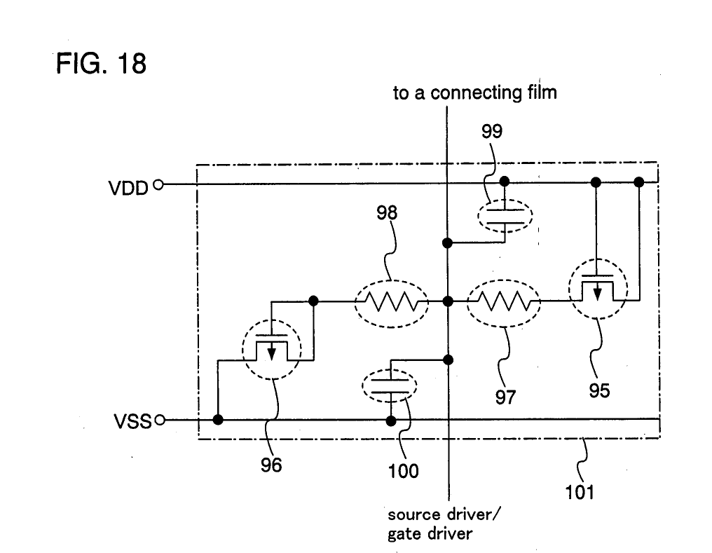

The display device of the invention includes a protection circuit 101 provided between a connecting film such as an FPC (Flexible Printed Circuit) and the first gate driver 41, the second gate driver 42 or the source driver 43 (see FIG. 18). As for the source driver 43, signals such as SCK, SSP, DataR, DataG, DataB, SLAT and SWE are supplied externally through the connecting film, and the protection circuit 101 is provided between a wiring for transmitting the signals and the connecting film. As for the first gate driver 41, signals such as GCK, G1SP, PWC and WE are supplied externally through the connecting film, and the protection circuit 101 is provided between the wiring for transmitting such signals and the connecting film. In the shown configuration, the protection circuit 101 includes transistors 95 and 96 each of which gate electrode and drain electrode are connected, resistors 97 and 98, and capacitors 99- and 100. This embodiment mode can be combined with the other embodiment modes of the present invention.

### Embodiment Mode 4

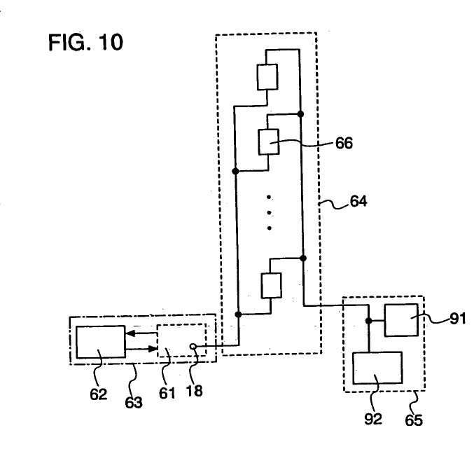

A temperature compensation function of the invention is implemented by using the monitoring circuit 64 that is operable in accordance with the ambient temperature, the control circuit 65 and the power source control circuit 63 (see FIG. 10). The monitoring circuit 64 includes the light emitting element 66 in the drawing. One of the electrodes of the light emitting element 66 is connected to a power source at a fixed potential (grounded in the drawing) while the other is connected to the control circuit 65. The control circuit 65 includes a constant current source 91 and an amplifier 92. The power source control circuit 63 includes the power source circuit 61 and the controller 62. Note that the power source circuit 61 is desirably a variable power source by which power source potentials to be supplied can be changed.

Description is made now on a mechanism for inspecting the ambient temperature using the light emitting element 66. A constant current is supplied between the opposite electrodes of the light emitting element 66 from the constant current source 91. That is, the current value of the light emitting element 66 is constant at all times. When the ambient temperature changes with such condition, a resistance value of the light emitting element 66 per se changes. When the resistance value of the light emitting element 66 changes, a potential difference is generated between the opposite electrodes of the light emitting element 66 since the current value of the light emitting element 66 is constant at all times. By inspecting the potential difference between the opposite electrodes of the light emitting element 66 generated by the change in temperature, the change in the ambient temperature is inspected. More specifically, the potential of an electrode of the light emitting element 66 at a fixed potential remains unchanged, therefore, a potential change of the opposite electrode that is connected to the constant current source 91 is inspected. A signal containing data on such potential change of the light emitting element is supplied to the amplifier 92, and amplified by the amplifier 92 to be outputted to the power source control circuit 63. The power source control circuit 63 changes a power source potential to be supplied to the pixel region 40 through the amplifier 92 based on the output of the monitoring circuit 64. Accordingly, the power source potential can be compensated in accordance with the temperature change. That is, fluctuations of a current value caused by the temperature change can be suppressed.

Note that a plurality of the light emitting elements 66 are provided in the drawing, however, the invention is not limited to this. The number of the light emitting elements 66 provided in the monitoring circuit 64 is not specifically limited. In addition, even when the light emitting element 66 is employed, a transistor may be connected in series to the light emitting element 66. In this case, the transistor connected in series to the light emitting element 66 is turned ON as required. Further, the light emitting element 66 is employed as the monitoring circuit 64, however, the invention is not limited to this and other known temperature sensors can be used. In the case of using a known temperature sensor, it may be provided on the same substrate as the pixel region 40, or connected externally by use of an IC. The temperature compensation function of the invention is free from a user's control, therefore, it can perform compensation continuously even after distributed to an end user. Thus, long life as a product can be achieved. This embodiment mode can be freely implemented in combination with the other embodiment modes of the present invention.

### Embodiment Mode 5

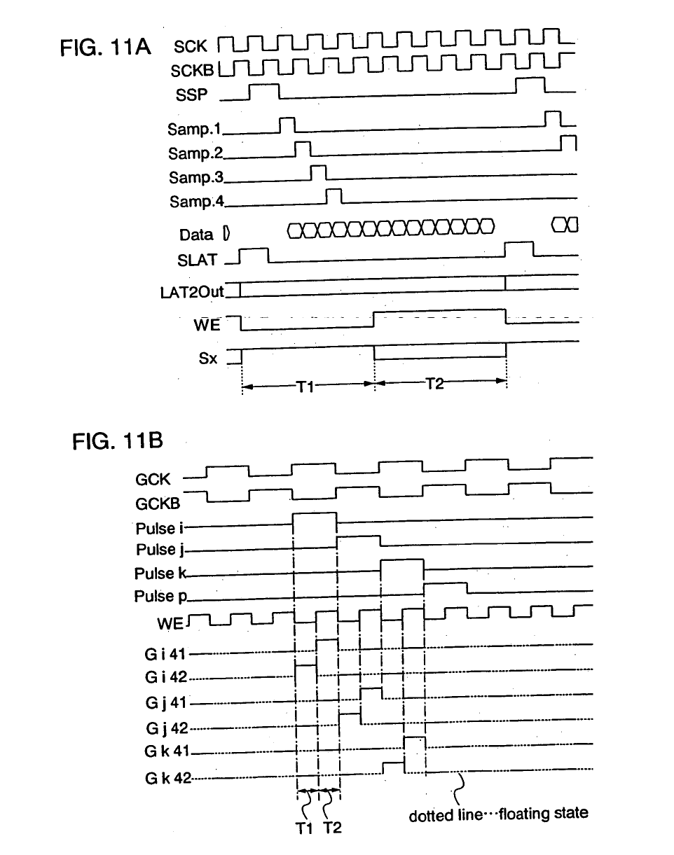

The operation of the display device of the invention is described with reference to FIGS. 4, 11A and 11B. First, the operation of the source driver is described (see FIGS. 4 and 11A). The pulse output circuit 44 is inputted with a clock signal (SCK), a clock inverted signal (SCKB) and a start pulse (SSP). In accordance with the timing of these signals, a sampling pulse is outputted to the first latch 47. The first latch 47 of the first to the last columns, to which data are inputted, stores video signals in accordance with the timing at which the sampling pulse is inputted. Upon input of a latch pulse, the video signals stored in the first latch 47 are transferred to the second latch 48 all at once.

Now, description is made on the operation of the selection circuit 46 in each period, assuming that the period in which a WE signal at L level is transmitted from the selection signal line 52 is T1 while the period in which a WE signal at H level is transmitted from the selection signal line 52 is T2. The periods T1 and T2 each corresponds to a half period of the horizontal scan period, and the period T1 is referred to as a first sub-gate selection period while the period T2 is referred to as a second sub-gate selection period.

In the period T1 (first sub-gate selection period), a WE signal transmitted from the selection signal line 52 is at L level, and the TFT 49 is ON whereas the analog switch 50 is OFF. Then, the plurality of signal lines S1 to Sn are electrically connected to the power source 53 through the TFT 49 that is provided in each column. That is, the plurality of signal lines S1 to Sn have the same potentials as the power source 53. At this time, the TFT 11 included in the pixel 10 is ON, and a potential of the power source 53 is transmitted to the gate electrode of the TFT 12 through the TFT 11. Then, the TFT 12 is turned OFF, and the opposite electrodes of the light emitting element 13 have the same potentials. That is, no current flows between the opposite electrodes of the light emitting element 13, thus it does not emit light. In this manner, the operation where a potential of the power source 53 is transmitted to the gate electrode of the TFT 12 regardless of the video signal inputted to the signal line, which turns OFF the TFT 11 to bring the opposite electrodes of the light emitting element 13 to have the same potentials is called an erasing operation.

In the period T2 (second sub-gate selection period), the WE signal transmitted from the selection signal line 52 is at H level, and the TFT 49 is OFF whereas the analog switch 50 is ON. Then, one row of the video signals stored in the second latch 48 are transmitted to the plurality of signal lines S1 to Sn all at once. At this time, the TFT 11 included in the pixel 10 is ON, and the video signal is transmitted to the gate electrode of the TFT 12 through the TFT 11. Then, according to the video signal inputted, the TFT 12 is turned ON or OFF, thereby the opposite electrodes of the light emitting element 13 have different potentials or the same potentials. More specifically, when the TFT 12 is turned ON, the opposite electrodes of the light emitting element 13 have different potentials, thereby current flows into the light emitting element 13. That is, the light emitting element 13 emits light. Note that current flowing into the light emitting element 13 has the same value as the source-drain current of the TFT 12. On the other hand, when the TFT 12 is turned OFF, the opposite electrodes of the light emitting element 13 have the same potentials, thereby no current flows into the light emitting element 13. That is, the light emitting element 13 does not emit light. In this manner, the operation where the TFT 12 is turned ON or OFF according to a video signal, thereby the opposite electrodes of the light emitting elements 13 have different potentials or the same potentials is called a writing operation.

Now, the operation of the first gate driver 41 and the second gate driver 42 is described. The pulse output circuit 54 is inputted with G1CK, G1CKB and G1SP. In accordance with the timing of these signals, pulses are sequentially outputted to the selection circuit 55. The pulse output circuit 56 is inputted with G2CK, G2CKB and G2SP. In accordance with the timing of these signals, pulses are sequentially outputted to the selection circuit 57. FIG. 11B illustrates a potential of a pulse that is supplied to each of the i, j, k and p-th rows (i, j, k and p are natural numbers, and 1≦i, j, k and p≦n is satisfied) of the selection circuits 55 and 57.

Now, similarly to the description on the operation of the source driver 43, description is made on the operation of the selection circuit 55 included in the first gate driver 41 and the selection circuit 57 included in the second gate driver 42 in each period, assuming that the period in which a WE signal at L level is transmitted from the selection signal line 52 is T1 while the period in which a WE signal at H level is transmitted from the selection signal line 52 is T2. Note that in the timing chart of FIG. 11B, a potential of the gate line Gy (y is a natural number, and 1≦y≦n is satisfied) which received a signal from the first gate driver 41 is denoted by Gy41 while a potential of the gate line which received a signal from the second gate driver 42 is denoted by Gy42. The Gy41 and Gy42 denote the same wiring.

In the period T1 (first sub-gate selection period), a WE signal transmitted from the selection signal line 52 is at L level. Then, the selection circuit 55 included in the first gate driver 41 is inputted with a WE signal at L level, thereby the selection circuit 55 is brought into a floating state. On the other hand, the selection circuit 57 included in the second driver 42 is inputted with an H-level signal that is inverted from the WE signal, thereby the selection circuit 57 is brought into an operating state. That is, the selection circuit 57 transmits an H-level signal (row selection signal) to the gate line Gi in the i-th row, thereby the gate line Gi has the same potential as the H-level signal. That is, the gate line Gi in the i-th row is selected by the second gate driver 42. As a result, the TFT 11 included in the pixel 10 is turned ON. Then, the potential of the power source 53 included in the source driver 43 is transmitted to the gate electrode of the TFT 12, thereby the TFT 12 is turned OFF and the two electrodes of the light emitting element 13 have the same potential to each other. That is, an erasing operation is performed in this period where the light emitting element 13 does not emit light.

In the period T2 (second sub-gate selection period), a WE signal transmitted from the selection signal line 52 is at H level. Then, the selection circuit 55 included in the first gate driver 41 is inputted with an WE signal at H level, thereby the selection circuit 55 is brought into the operating state. That is, the selection circuit 55 transmits an H-level signal to the gate line Gi in the i-th row, thereby the gate line Gi has the same potential as the H-level signal. That is, the gate line Gi in the i-th row is selected by the first gate driver 41. As a result, the TFT 11 included in the pixel 10 is turned ON. Then, a video signal is transmitted from the second latch 48 included in the source driver 43 to the gate electrode of the TFT 12, thereby the TFT 12 is turned ON or OFF, and the two electrodes of the light emitting element 13 have different potentials or the same potentials. That is, in this period, writing operation is performed where the light emitting element 13 emits light or no light. On the other hand, the selection circuit 57 included in the second gate driver 42 is inputted with an L-level signal, thereby it is brought into the floating state.

In this manner, the gate line Gy is selected by the second gate driver 42 in the period T1 (first sub-gate selection period) while it is selected by the first gate driver 41 in the period T2 (second sub-gate selection period). That is, the gate line is controlled by the first gate driver 41 and the second gate driver 42 in a complementary manner. In addition, the erasing operation is performed in one of the first sub-gate selection period and the second sub-gate selection period while the writing operation is performed in the other period.

Note that in the period in which the gate line Gi in the i-th row is selected by the first gate driver 41, the second gate driver 42 is not in the operating state (the selection circuit 57 is in the floating state), or transmits a row selection signal to the gate line of the rows other than the i-th row. Similarly, in the period in which the gate line Gi in the i-th row receives a row selection signal from the second gate driver 42, the first gate driver 41 is in the floating state, or transmits a row selection signal to the gate line of the rows other than the i-th row.

According to the invention that performs the above operation, the light emitting element 13 can be forcibly turned OFF, therefore, the duty ratio can be improved even when the number of gray scales is increased. Further, there is no need to provide a TFT for releasing a charge of the capacitor 16 although the light emitting element 13 can be forcibly turned OFF. Thus, a high aperture ratio can be achieved. When a high aperture ratio is achieved, luminance of the light emitting elements can be decreased in accordance with the increase in light emitting areas, which contributes to reduction in power consumption. That is, a drive voltage can be decreased to reduce power consumption.

Note that the invention is not limited to the aforementioned mode where the gate selection period is divided in half. The gate selection period may be divided into three or more periods. This embodiment mode can be freely implemented in combination with the aforementioned embodiment mode.

Note also that an erasing signal is inputted to a pixel in the former half of the gate selection period (first sub-gate selection period) while a video signal is inputted to a pixel in the latter half of the gate selection period (second sub-gate selection period), however, the invention is not limited to this. It is also possible that a video signal is inputted to a pixel in the former half of the gate selection period (first sub-gate selection period) while an erasing signal is inputted to a pixel in the latter half of the gate selection period (second sub-gate selection period).

Alternatively, it is also possible that a video signal is inputted to a pixel in the former half of the gate selection period (first sub-gate selection period), and another video signal is inputted to a pixel in the latter half of the gate selection period (second sub-gate selection period). A signal corresponding to a different sub-frame may be inputted in each period. As a result, sub-frame periods can be provided without the need of an erasing period so that light emitting periods are arranged in succession. As there is no need to provide an erasing period in such a case, the duty ratio can be increased.

### Embodiment Mode 6

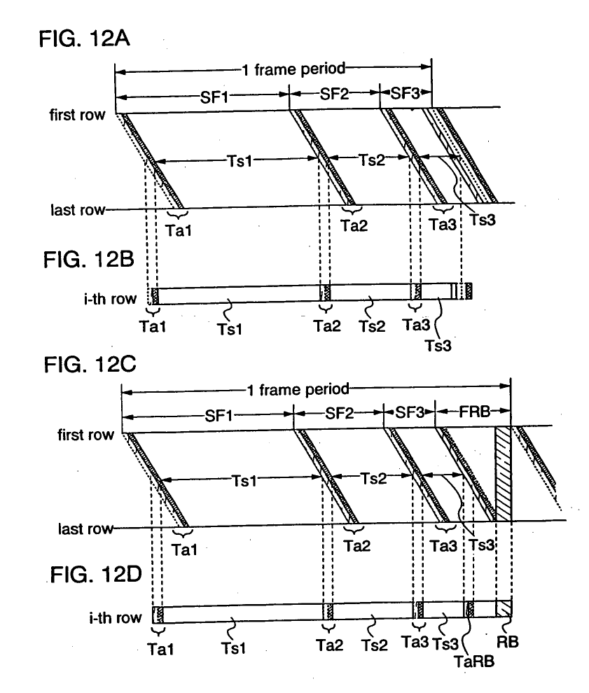

Description is made below on the operation of the display device of the invention with reference to timing charts (FIGS. 12A and 12C) whose ordinate denotes a scan line while abscissa denotes time, and timing charts (FIGS. 12B and 12D) of the gate line Gi (1≦i≦m) in the i-th row. In the time gray scale method, one frame period includes a plurality of sub-frame periods SF1, SF2, . . . , SFn (n is a natural number). Each of the plurality of sub-frame periods includes one of a plurality of writing periods Ta1, Ta2, . . . , Tan in which the writing operation or the erasing operation is performed, and one of a plurality of light emitting elements Ts1, Ts2 . . . , Tsn. Each of the plurality of writing periods includes a plurality of gate selection periods. Each of the plurality of gate selection periods includes a plurality of sub-gate selection periods. The number into which each gate selection period is divided is not specifically limited, however, it is preferably 2 to 8, or more preferably 2 to 4. The length of the light emitting periods Ts1:Ts2: . . . :Tsn is set to satisfy, for example, 2⁽ⁿ⁻¹⁾:2⁽ⁿ⁻²⁾: . . . :2¹:2⁰. That is, the light emitting periods Ts1, Ts2, . . . , Tsn are set to have different length for each bit.

Description is made below on the timing chart for displaying 3-bit gray scales (8 gray scales) in the case of providing no AC drive period FRB (Frame Reverse Bias) (see FIGS. 12A and 12B). In this case, one frame period is divided into three sub-frame periods SF1 to SF3. Each of the sub-frame periods SF1 to SF3 includes one of the writing periods Ta1 to Ta3, and one of the light emitting periods Ts1 to Ts3. Each writing period includes a plurality of gate selection periods. Each of the plurality of gate selection periods includes a plurality of sub-gate selection periods. Here, each of the gate selection periods includes two sub-gate selection periods: the first sub-gate selection period for performing the erasing operation, and the second sub-gate selection period for performing the writing operation.

Note that the erasing operation is the operation for bringing the light emitting element to emit no light, and it is performed only when necessary in a sub-frame period.

Description is made below on the timing chart in the case of providing an AC drive period RFB (see FIGS. 12C and 12D). The AC drive period FRB includes a writing period TaRB in which only an erasing operation is performed, and a reverse bias application period in which a reverse bias is applied to the whole light emitting elements simultaneously by reversing the potential levels supplied to the light emitting element. Note that the AC drive period FRB is not necessarily provided per frame period, and it may be provided per several frame periods. In addition, the AC drive period FRB is not required to be provided separately from the sub-frame periods SF1 to SF3, and it may be provided in the light emitting periods Ts1 to Ts3 within a certain sub-frame period.

In addition, the order of the sub-frame periods is not limited to the above in which the sub-frame periods are arranged in order from the higher-order bit to the lower-order bit, and they may be arranged at random. Further, the order of the sub-frame periods may be random per frame period. In addition, one or more periods selected from the sub-frame periods may be divided into a plurality of periods. In that case, each of the one or more divided sub-frame periods, and each of the one or more undivided sub-frame periods includes one of the plurality of writing periods Ta1, Ta2, . . . , Tam (m is a natural number), and one of the plurality of light emitting periods Ts1, Ts2, . . . , Tsm.

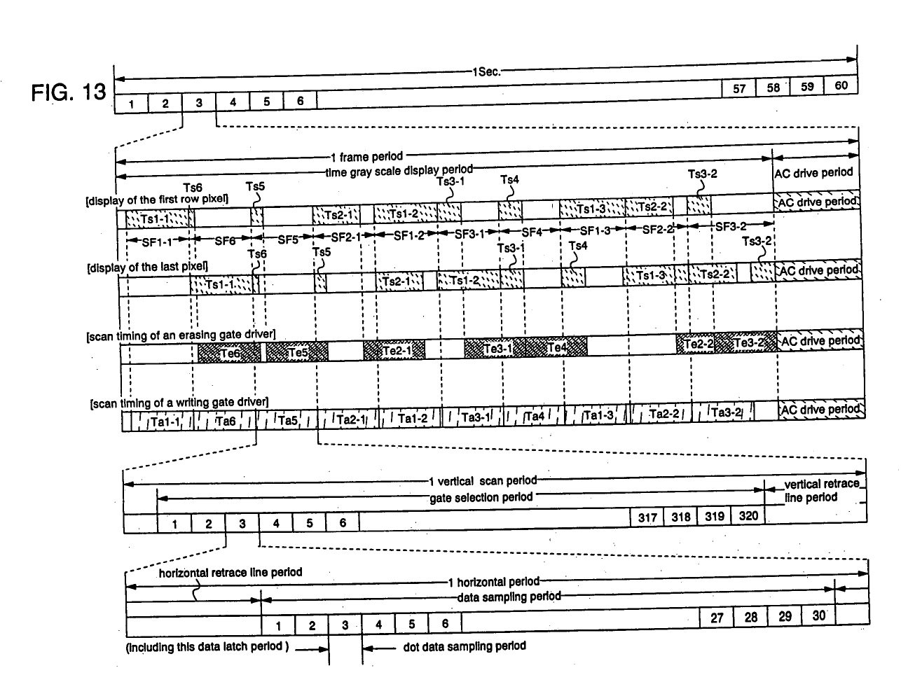

Now, description is made on a timing chart where a sub-frame period of the high-order bit is divided into a plurality of periods, and the order of the sub-frame periods is random (see FIG. 13). The timing chart illustrates the case of displaying 6-bit gray scales where the sub-frame period SF1 is divided into three (denoted by SF1-1 to SF1-3), the sub-frame period SF2 is divided into two (denoted by SF2-1 and SF2-2), and the sub-frame period SF3 is divided into two (denoted by SF3-1 and SF3-2). It also illustrates the display timing of a pixel of the first row, the display timing of the pixel of the last row, the scan timing of an erasing gate driver, and the scan timing of a writing gate driver. Note that the display duty ratio of the shown timing chart is 51%. This embodiment mode can be freely implemented in combination with the aforementioned embodiment modes.

### Embodiment Mode 7

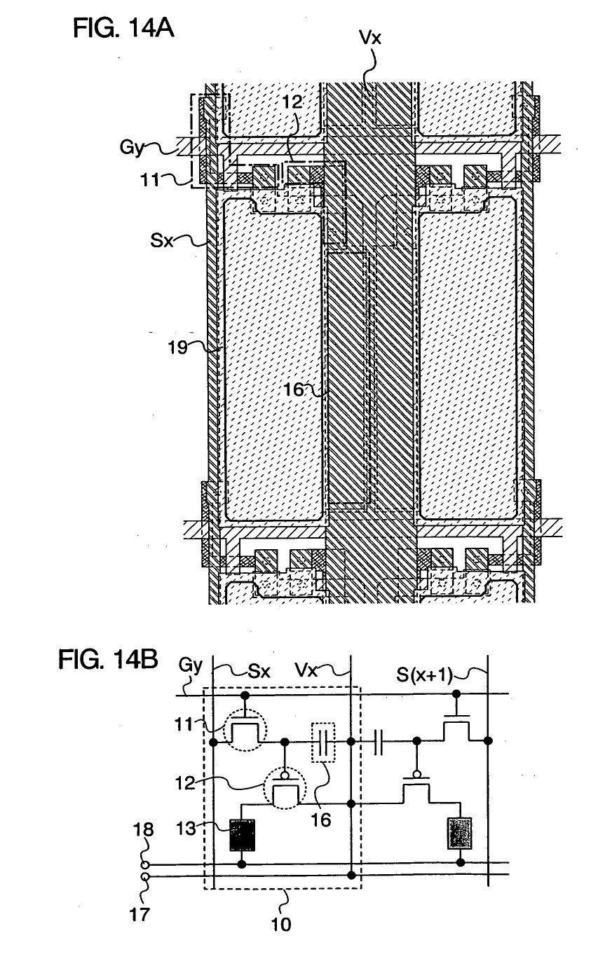

Description is made now with reference to FIGS. 14A and 14B on a mode of the display device of the invention where the power source line Vx is shared by adjacent pixels. Note that the display device comprises a plurality of the pixels 10 each of which includes the light emitting element 13, the capacitor 16 and the TFTs 11 and 12 as set forth above. When the power source line Vs is shared by adjacent pixels, the arrangement of the adjacent pixels is horizontally rotated. When the power source line Vx is shared by the adjacent pixels, the number of the wirings necessary can be decreased, which leads to a high aperture ratio. When a high aperture ratio is achieved, luminance of the light emitting elements can be decreased in accordance with the increase in light emitting areas, which contributes to reduction in power consumption. That is, a drive voltage can be decreased to reduce power consumption.

In the case of adopting the structure above, it is desirable to employ light emitting elements exhibiting monochromatic light or white light. By providing a filter or a color conversion layer on the side to which light is emitted, color display can be performed. When the power source line is shared in this manner, compensation of power source potentials for degradation can be easily performed in the case of adopting the structure where monochromatic light or white light is obtained than the case of selectively coloring electroluminescent layers. This embodiment mode can be freely implemented in combination with the aforementioned embodiment modes.

### Embodiment Mode 8

The display device of the invention may be provided with a polarizing plate, a wave plate or a circular polarizing plate in order to enhance contrast. Each of the light emitting elements included in the display device of the invention has a pair of electrodes and an electroluminescent layer interposed therebetween. In the case of performing color display, it is desirable to form an electroluminescent layer having a different emission spectrum in each pixel, in which case electroluminescent layers corresponding to red (R), green (G) and blue (B) respectively are formed typically. In this case, color purity can be improved and mirror surface reflection (glare) can be prevented by providing a filter (colored layer) for transmitting light within the emission spectrum on the side to which light is emitted from the light emitting elements. In addition, when such a filter is provided, a circular polarizing plate that has been conventionally required can be omitted, which can recover the loss of light emitted from the electroluminescent layers. Further, change in color tone that is recognized when seeing the display area obliquely can be reduced. In addition, the electroluminescent layer can have a structure to exhibit monochromatic light or white light. In the case of adopting a white light emitting material, color display can be performed by providing a filter for transmitting light within a specific emission spectrum on the side to which light is emitted from the light emitting elements.

The electroluminescent layer is formed of a material for light emission that is obtained from a singlet excitation (hereinafter referred to as a singlet excitation material), or a material for light emission that is obtained from a triplet excitation (hereinafter referred to as a triplet excitation material). For example, among light emitting elements for red emission, green emission and blue emission, the light emitting element for red emission of which luminance half decay period (time until which the luminance decays to the half level of its original value) is relatively short is formed of a triplet excitation material while the other light emitting elements are formed of a singlet excitation material. The triplet excitation material has high luminous efficiency, which is advantageous in that lower power consumption is required even for obtaining the same luminance. Alternatively, the light emitting elements for red emission and green emission may be formed of a triplet excitation light emitting material while the light emitting element for blue emission may be formed of a singlet excitation material. When forming the light emitting element for green emission that is highly visible to human eyes by using a triplet excitation material, even lower power consumption can be achieved. As an example of the triplet excitation material, there is the one using a metal complex as a dopant, which includes a metal complex having, as a central atom, platinum that is a third transition element, and a metal complex having, as a central atom, iridium, and the like.

The light emitting element may have either a forward stacking structure where an anode, an electroluminescent layer and a cathode are stacked in this order, or an inversely stacking structure where a cathode, an electroluminescent layer and an anode are stacked in this order. The electrodes of the light emitting element are desirably formed of ITO (Indium Tin Oxide), or ITSO (silicon-doped ITO), IZO or GZO. This embodiment mode can be freely implemented in combination with the aforementioned embodiment modes.

### Embodiment Mode 9

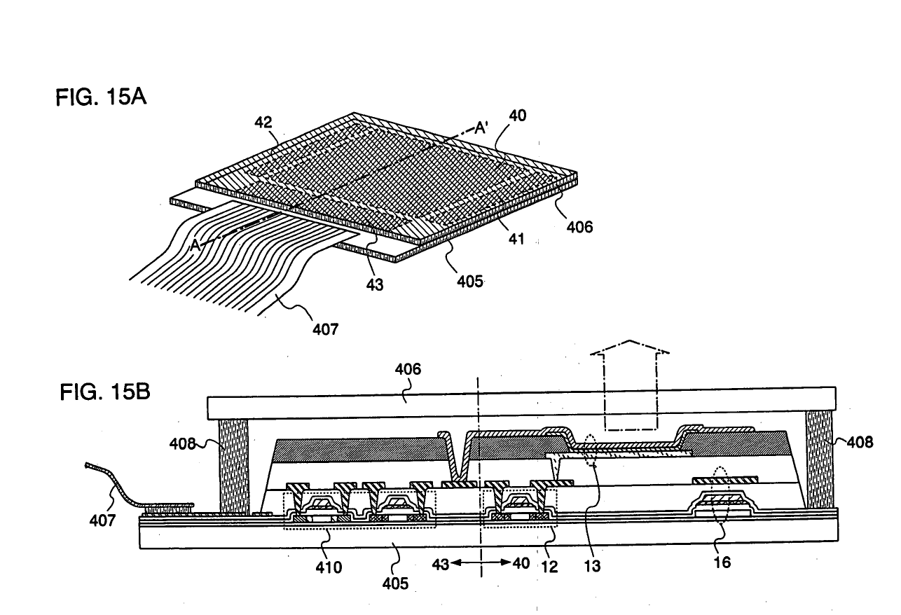

Description is made on a panel as a mode of the light emitting device of the invention where the pixel region 40, the first gate driver 41, the second gate driver 42 and the source driver 43 are mounted. Over a substrate 405, the pixel region 40 including a plurality of pixels each of which has the light emitting element 13, the first gate driver 41, the second gate driver 42, the source driver 43 and a connecting film 407 are formed (see FIG. 15A). The connecting film 407 is connected to an external circuit (IC chip).

FIG. 15B is a cross-sectional diagram of the panel in FIG. 15A along a line A-A′, which illustrates the TFT 12 and the light emitting element 13 provided in the pixel region 40, and a CMOS circuit 410 provided in the source driver 43. A sealant 408 is provided around the pixel region 40, the first gate driver 41, the second gate driver 42 and the source driver 43, and the light emitting element 13 is sealed by the sealant 408 and the counter substrate 406. This sealing process is performed for protecting the light emitting element 13 from moisture, and a covering material (glass, ceramics, plastic, metal or the like) is used for sealing here. Alternatively, other methods may be employed for sealing by use of a heat curable resin, an ultraviolet light curable resin, or by use of a thin film having a high barrier property such as a metal oxide film and a nitride film. Elements formed over the substrate 405 are preferably formed of crystalline semiconductors (polysilicon) having superior properties such as mobility as compared to amorphous semiconductors, which enables monolithic integration on the same surface. According to a panel having the structure above, the number of external ICs to be connected can be reduced, which enables downsizing, weight saving and thinner shape.

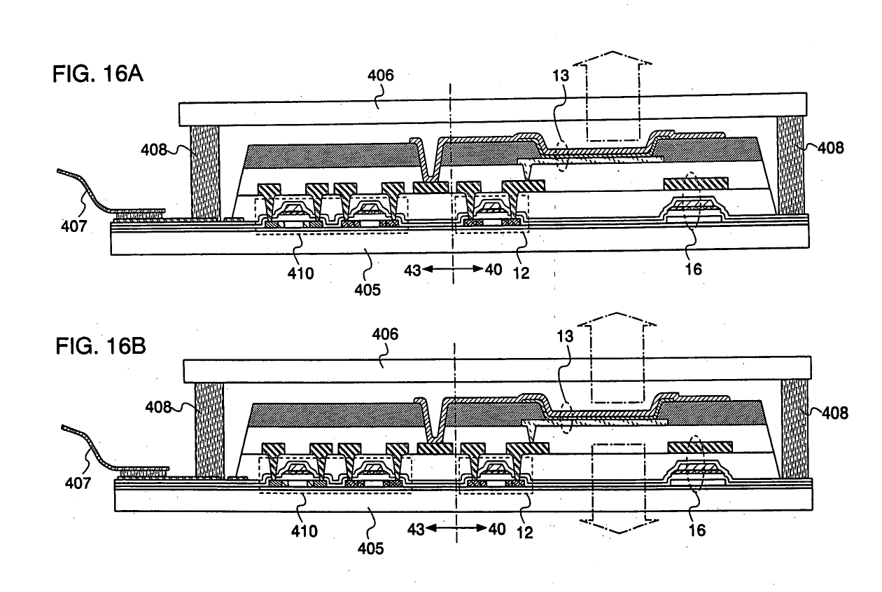

Note that in the structure above, the pixel electrode of the light emitting element 13 transmits light while the counter electrode of the light emitting element 13 shields light. Accordingly, the light emitting element 13 emits light to the bottom side. Alternatively, another structure may be employed in addition to the structure above where the pixel electrode of the light emitting element 13 shields light while the counter electrode of the light emitting element 13 transmits light (see FIG. 16A). In this case, the light emitting element 13 emits light to the top side.

Further, a still another structure may be employed in addition to the structure above where both of the pixel electrode and the counter electrode of the light emitting element 13 transmit light (see FIG. 16B). In this case, the light emitting element 13 emits light to both sides.

The display device of the invention may adopt any of the bottom emission, top emission or dual emission structure. In the case of the bottom emission or dual emission structure adopted, a conductive layer (source/drain wiring) connected to the impurity regions included in the TFT 12 is preferably formed of a combination of aluminum (Al) and a low reflective material such as molybdenum (Mo). Specifically, a stacked-layer structure of molybdenum (Mo), aluminum-silicon (Al—Si) and molybdenum (Mo), a stacked-layer structure of molybdenum nitride (MoN), aluminum-silicon (Al—Si) and molybdenum nitride (MoN), or the like is preferably adopted. Accordingly, it can be prevented that light emitted from the light emitting elements is reflected on the source/drain wiring. Thus, light can be extracted to outside.

Note that the pixel region 40 is constituted by TFTs whose channel portions are formed of amorphous semiconductors (amorphous silicon) formed over an insulating surface while the first gate driver 41, the second gate driver 42 and the source driver 43 are formed of IC chips. The IC chips may be attached to the substrate 405 by COG bonding or attached to the connecting film 407 for connection to the substrate 405. Amorphous semiconductors can be formed easily over a large substrate by CVD, which does not require crystallization steps. Therefore, an inexpensive panel can be provided. In addition, when the conductive layer is formed by a droplet discharge method represented by ink-jetting, even more inexpensive panel can be provided. This embodiment mode can be freely implemented in combination with the aforementioned embodiment modes.

### Embodiment Mode 10

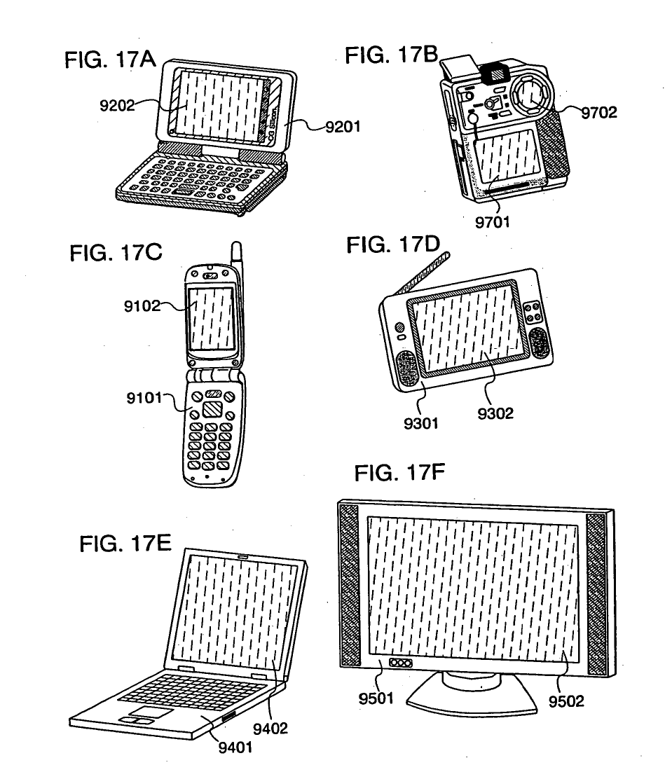

A display device comprising a pixel region including light emitting elements can be applied to electronic appliances such as a television set (television or television receiver), a digital camera, a digital video camera, a portable phone set (portable phone), a portable information terminal (e.g., PDA), a portable game machine, a monitor, a computer, a sound reproducing device (e.g., car stereo), and an image reproducing device provided with a recording medium such as a domestic game machine. FIGS. 17A to 17F illustrate specific examples of such apparatuses.

A portable information terminal using the display device of the invention shown in FIG. 17A includes a main body 9201, a display portion 9202 and the like, of which low power consumption can be achieved by the invention. A digital video camera using the display device of the invention shown in FIG. 17B includes display portions 9701 and 9702 and the like, of which low power consumption can be achieved by the invention. A portable information terminal using the display device of the invention shown in FIG. 17C includes a main body 9101, a display portion 9102 and the like, of which low power consumption can be achieved by the invention. A portable television set using the display device of the invention shown in FIG. 17D includes a main body 9301, a display portion 9302 and the like, of which low power consumption can be achieved by the invention. A portable computer using the display device of the invention shown in FIG. 17E includes a main body 9401, a display portion 9402 and the like, of which low power consumption can be achieved by the invention. A television set using the display device of the invention shown in FIG. 17F includes a main body 9501, a display portion 9502 and the like, of which low power consumption can be achieved by the invention. Among the electronic appliances set forth above, those using batteries can ensure a longer operating time by the amount of the power consumption reduced, which can save the battery charging time.

### Embodiment 1

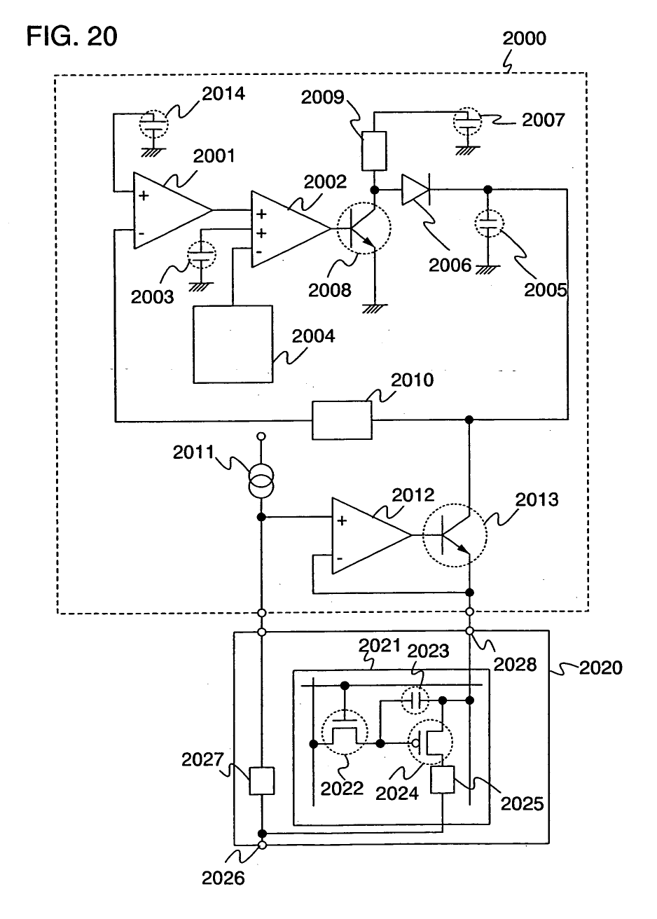

FIG. 20 illustrates a specific example of a circuit for compensating the temperature characteristics and the luminance characteristics. It includes a display panel 2020 and a power source 2000. The power source 2000 corresponds to the control circuit 65 of the display device shown in FIG. 4 of Embodiment Mode 1. The display panel includes a pixel portion 2021, a monitoring element 2027 and a first power source terminal 2026. The pixel portion 2021 includes a switching TFT 2022, a storage capacitor 2023, a driving TFT 2024 and a light emitting element 2025. When the driving TFT 2024 is turned ON to connect the light emitting element 2025 to a second power source terminal 2028, the light emitting element 2025 emits light.

The current-voltage characteristics of the light emitting element 2025 change according to the temperature. In the case of applying a constant voltage, high luminance is obtained at high temperature while low luminance is obtained at low temperature. In order to compensate this, a constant current is supplied to the monitoring element 2027 from a constant current source 2011, and a voltage generated therein is applied to the second power source terminal 2028 through a transistor 2013. When the monitoring element 2027 and the light emitting element 2025 are formed of the same materials, the temperature characteristics are cancelled, thereby luminance can be maintained constant relatively to the temperature.

The power source 2000 is a switching regulator, which includes a first comparator 2001, a second comparator 2002, an oscillator circuit 2004, a smoothing capacitor 2005, a diode 2006, a switching transistor 2008, an inductor 2009, reference power supplies 2003, 2007 and 2014, and an attenuator 2010. The reference power source 2007 is a power source having a high current capacity such as a battery.

The configuration of the switching regulator is not limited to the above, and other configurations may be employed. In addition, FIG. 20 illustrates the switching transistor being an NPN bipolar transistor, however, the invention is not limited to this.

The output signal of the oscillator circuit 2004, the reference power source 2003 and the output signal of the first comparator 2001 are compared to one another in the second comparator 2002, and the output signal of the second comparator 2002 turns ON/OFF the switching transistor 2008. When the switching transistor 2008 is turned ON, current flows into the inductor 2009, thereby magnetic energy is stored in the inductor 2009. When the switching transistor 2008 is turned OFF, the magnetic energy is transformed to a voltage, thereby the smoothing capacitor 2005 is charged through the diode 2006. A DC voltage generated in the smoothing capacitor changes according to the ON/OFF duty of the switching transistor 2008.

The D C voltage of the smoothing capacitor 2005 is attenuated in the attenuator 2010, which is then inputted to the first comparator 2001. The first comparator 2001 compares the reference power source 2014 with the voltage of the attenuator 2010, of which output is inputted to the second comparator 2002. In this manner, feedback operation is performed and a necessary voltage can be generated in the smoothing capacitor 2005. Here, the constant current source 2011, the amplifier 2012 and the monitoring element 2027 are connected directly, however, other elements such as a resistor and a switch may be interposed therebetween.

### Embodiment 2

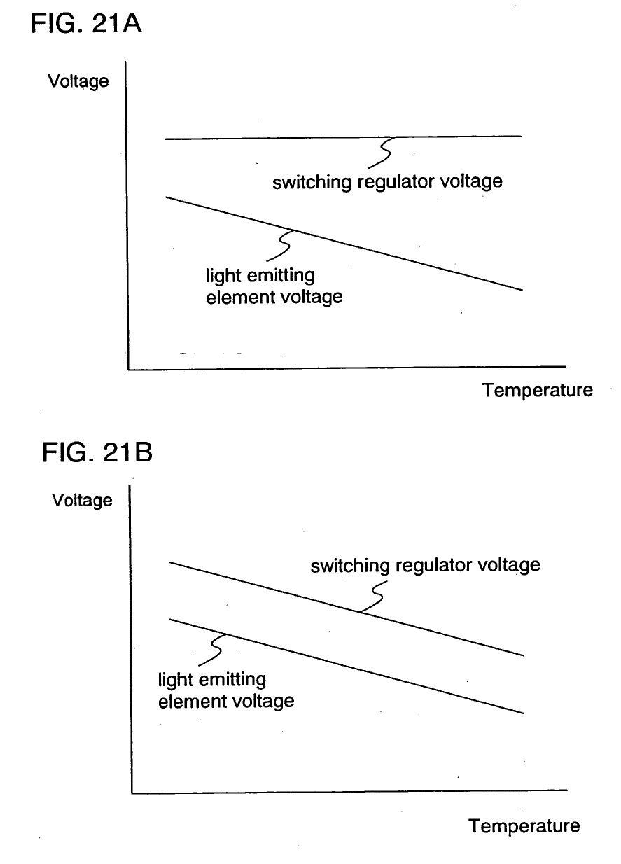

In embodiment shown in FIG. 20, a voltage of the smoothing capacitor 2005 has a constant value independently of the temperature, however, the light emitting element has the temperature characteristics. Generally, a voltage of a light emitting element is high at low temperature while low at high temperature. FIG. 21A illustrates such phenomenon. At high temperature, there is a large difference between the light emitting element voltage and the smoothing capacitor voltage (denoted by the switching regulator voltage in FIGS. 21A and 21B), which produces wasteful power consumption. If the switching regulator voltage is decreased in conjunction with the light emitting element voltage at high temperature as shown in FIG. 21B, wasteful power consumption can be reduced.

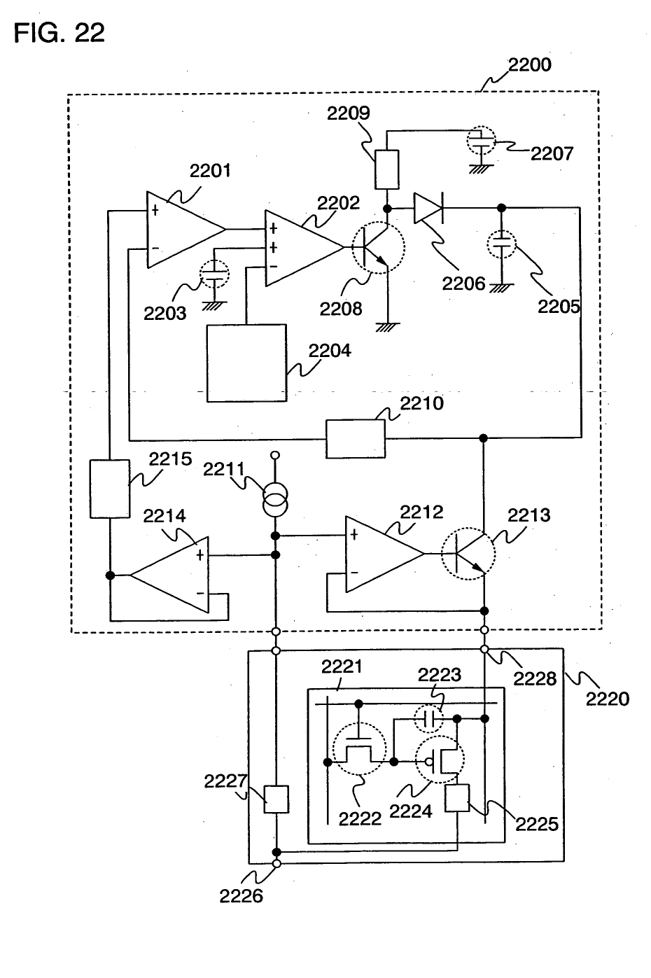

FIG. 22 is an embodiment contrived in order to solve such a problem. A monitoring element voltage is inputted to the switching regulator so that the switching regulator voltage operates in conjunction with the light emitting element voltage.

FIG. 22 illustrates a specific example of a circuit for compensating the temperature characteristics and the luminance characteristics. It includes a display panel 2220 and a power source 2200. The power source 2200 corresponds to the control circuit 65 of the display device shown in FIG. 4 of Embodiment Mode 1. The display panel includes a pixel portion 2221, a monitoring element 2227 and a first power source terminal 2226. The pixel portion 2221 includes a switching TFT 2222, a storage capacitor 2223, a driving TFT 2224 and a light emitting element 2225. When the driving TFT 2224 is turned ON to connect the light emitting element 2225 to a second power source terminal 2228, the light emitting element 2225 emits light.

The current-voltage characteristics of the light emitting element 2225 change according to the temperature. In the case of applying a constant voltage, high luminance is obtained at high temperature while low luminance is obtained at low temperature. In order to make compensate this, a constant current is supplied to the monitoring element 2227 from a constant current source 2211, and a voltage generated therein is applied to the second power source terminal 2228 through an amplifier 2212 and a transistor 2213. When the monitoring element 2227 and the light emitting element 2225 are formed of the same materials, the temperature characteristics are cancelled, thereby luminance can be maintained constant relatively to the temperature.

The power source 2200 is a switching regulator, which includes a first comparator 2201, a second comparator 2202, an oscillator circuit 2204, a smoothing capacitor 2205, a diode 2206, a switching transistor 2208, an inductor 2209, reference power supplies 2203 and 2207, and an attenuator 2210. The reference power source 2207 is a power source having a high current capacity such as a battery.

The configuration of the switching regulator is not limited to the above, and other configurations may be employed. In addition, FIG. 22 illustrates the switching transistor being an NPN bipolar transistor, however, the invention is not limited to this.

The output signal of the oscillator circuit 2204, the reference power source 2203 and the output signal of the first comparator 2201 are compared with one another in the second comparator 2202, and the output signal of the second comparator 2202 turns ON/OFF the switching transistor 2208. When the switching transistor 2208 is turned ON, current flows into the inductor 2209, thereby magnetic energy is stored in the inductor 2209. When the switching transistor 2208 is turned OFF, the magnetic energy is transformed to a voltage, thereby the smoothing capacitor 2205 is charged through the diode 2206. A DC voltage generated in the smoothing capacitor changes according to the ON/OFF duty of the switching transistor 2208.

A voltage of the monitoring element 2227 is inputted to the first comparator 2201 through the amplifier 2214 and the attenuator 2215. The DC voltage of the smoothing capacitor 2205 is attenuated in the attenuator 2210, which is then inputted to the first comparator 2201. The first comparator 2201 compares the voltage of the attenuator 2215 and the voltage of the attenuator 2210, of which output is inputted to the second comparator 2202. In this manner, feedback operation is performed and a necessary voltage can be generated in the smoothing capacitor 2205. Here, the constant current source 2211, the amplifiers 2212 and 2214, and the monitoring element 2227 are connected directly, however, other elements such as a resistor and a switch may be interposed therebetween.

### Embodiment 3

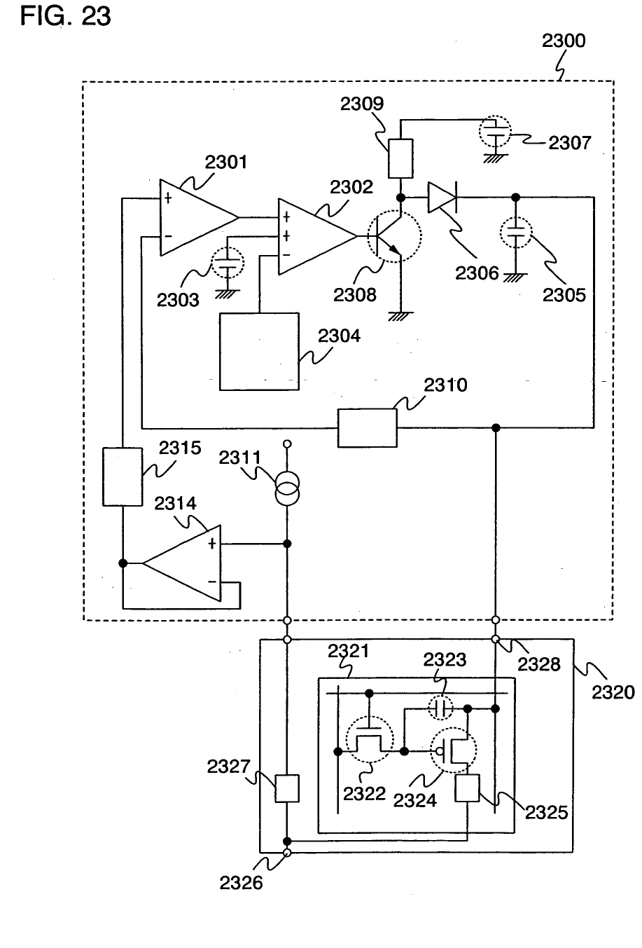

FIG. 23 is an embodiment where the output of the switching regulator is directly connected to the second power source terminal of the display panel. The voltage of the monitoring element is inputted to the switching regulator so that the voltage of the switching regulator operates in conjunction with the voltage of the light emitting element.

FIG. 23 illustrates a specific example of a circuit for compensating the temperature characteristics and the luminance characteristics. It includes a display panel 2320 and a power source 2300. The power source 2300 corresponds to the control circuit 65 of the display device shown in FIG. 4 of Embodiment Mode 1. The display panel includes a pixel portion 2321, a monitoring element 2327 and a first power source terminal 2326. The pixel portion 2321 includes a switching TFT 2322, a storage capacitor 2323, a driving TFT 2324 and a light emitting element 2325. When the driving TFT 2324 is turned ON to connect the light emitting element 2325 to a second power source terminal 2328, the light emitting element 2325 emits light.

The current-voltage characteristics of the light emitting element 2325 change according to the temperature. In the case of applying a constant voltage, high luminance is obtained at high temperature while low luminance is obtained at low temperature. In order to compensate this, a constant current is supplied to the monitoring element 2327 from a constant current source 2311, and a switching regulator voltage generated therein is applied to the second power source terminal 2328. When the monitoring element 2327 and the light emitting element 2325 are formed of the same materials, the temperature characteristics are cancelled, thereby luminance can be maintained constant relatively to the temperature. The compensation circuit in this embodiment has lower stability, however, it has the advantage in that the number of amplifiers and transistor can be reduced.

The power source 2300 is a switching regulator, which includes a first comparator 2301, a second comparator 2302, an oscillator circuit 2304, a smoothing capacitor 2305, a diode 2306, a switching transistor 2308, an inductor 2309, reference power supplies 2303 and 2307, and an attenuator 2310. The reference power source 2307 is a power source having a high current capacity such as a battery. The output signal of the oscillator circuit 2304, the reference power source 2303 and the output signal of the first comparator 2301 are compared one another in the second comparator 2302, and the output signal of the second comparator 2302 turns ON/OFF the switching transistor 2308. When the switching transistor 2308 is turned ON, current flows into the inductor 2309, thereby magnetic energy is stored in the inductor 2309. When the switching transistor 2308 is turned OFF, the magnetic energy is transformed to a voltage, thereby the smoothing capacitor 2305 is charged through the diode 2306. A DC voltage generated in the smoothing capacitor changes according to the ON/OFF duty of the switching transistor 2308.

The voltage of the monitoring element 2327 is inputted to the first comparator 2301 through an amplifier 2314 and an attenuator 2315. The DC voltage of the smoothing capacitor 2305 is attenuated in the attenuator 2310, and then inputted to the first comparator 2301. The first comparator 2301 compares the voltage of the attenuator 2315 with the voltage of the attenuator 2310, of which output is inputted to the second comparator 2302. In this manner, feedback operation is performed and a necessary voltage can be generated in the smoothing capacitor 2305. Here, the constant current source 2311, the amplifier 2314 and the monitoring element 2327 are connected directly, however, other elements such as a resistor and a switch may be interposed therebetween.

### Embodiment 4

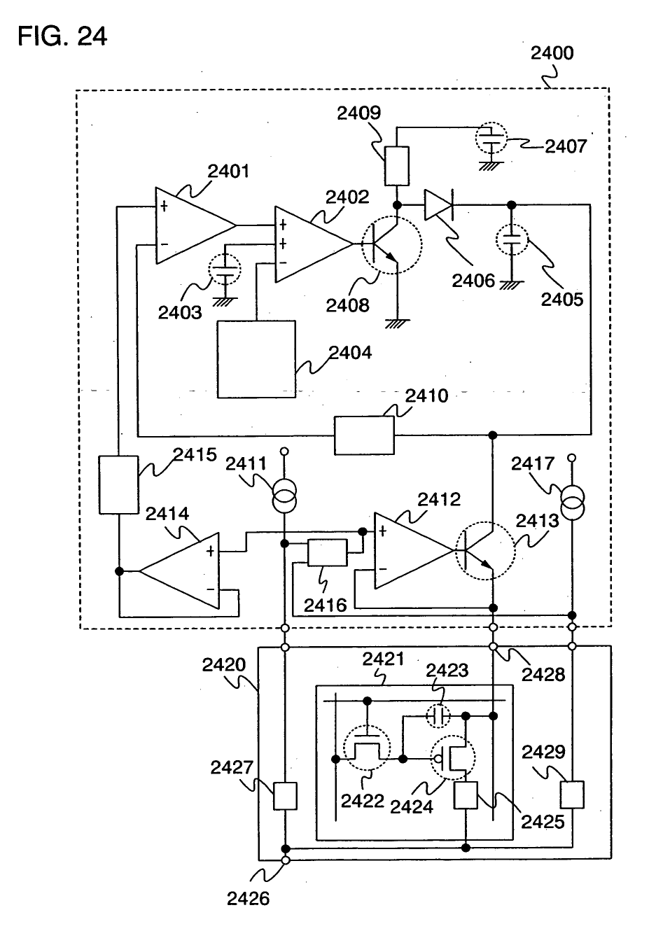

FIG. 24 illustrates an embodiment where a plurality of monitoring elements are provided. Voltages of the plurality of monitoring elements are inputted to the switching regulator so that the voltage of the switching regulator operates in conjunction with the voltage of the light emitting element.

FIG. 24 is a specific example of a circuit for compensating the temperature characteristics and the luminance characteristics. It includes a display panel 2420 and a power source 2400. The power source 2400 corresponds to the control circuit 65 of the display device shown in FIG. 4 of Embodiment Mode 1. The display panel includes a pixel portion 2421, a monitoring element 2427, a monitoring element 2429 and a first power source terminal 2426. The pixel portion 2421 includes a switching TFT 2422, a storage capacitor 2423, a driving TFT 2424 and a light emitting element 2425. When the driving TFT 2424 is turned ON to connect the light emitting element 2425 to a second power source terminal 2428, the light emitting element 2425 emits light.

The current-voltage characteristics of the light emitting element 2425 change according to the temperature. In the case of applying a constant voltage, high luminance is obtained at high temperature while low luminance is obtained at low temperature. In order to compensate this, a constant current is supplied to the monitoring element 2427 and the monitoring element 2729 from a constant current source 2411 and a constant current source 2427 respectively, and a voltage generated therein is applied to the second power source terminal 2428 through an amplifier 2412 and a transistor 2413. When the monitoring element 2427, the monitoring element 2429 and the light emitting element 2425 are formed of the same materials, the temperature characteristics are cancelled, thereby luminance can be maintained constant relatively to the temperature. When two monitoring elements are disposed on both sides of the pixel portion and connected to the amplifiers 2412 and 2414 after being averaged by an adder circuit 2416, even more accurate monitoring can be performed. Further, according to the invention, the number of the monitoring elements can be further increased. When the number of the monitoring elements is increased, the difference between the monitoring elements and the light emitting element can be reduced.

The power source 2400 is a switching regulator, which includes a first comparator 2401, a second comparator 2402, an oscillator circuit 2404, a smoothing capacitor 2405, a diode 2406, a switching transistor 2408, an inductor 2409, reference power supplies 2403 and 2407, and an attenuator 2410. The reference power source 2407 is a power source having a high current capacity such as a battery. The output signal of the oscillator circuit 2404, the reference power source 2403 and the output signal of the first comparator 2401 are compared one another in the second comparator 2402, and the output signal of the second comparator 2402 turns ON/OFF the switching transistor 2408. When the switching transistor 2408 is turned ON, current flows into the inductor 2409, thereby magnetic energy is stored in the inductor 2409. When the switching transistor 2408 is turned OFF, the magnetic energy is transformed to a voltage, thereby the smoothing capacitor 2405 is charged through the diode 2406. A DC voltage generated in the smoothing capacitor changes according to the ON/OFF duty of the switching transistor 2408.

The voltages of the monitoring element 2427 and the monitoring element 2429 are inputted to the first comparator 2401 through the adder circuit 2416, the amplifier 2414 and the attenuator 2415. The DC voltage of the smoothing capacitor 2405 is attenuated in the attenuator 2410, and then inputted to the first comparator 2401. The first comparator 2401 compares the voltage of the attenuator 2415 with the voltage of the attenuator 2410, of which output is inputted to the second comparator 2402.

In this manner, feedback operation is performed and a necessary voltage can be generated in the smoothing capacitor 2405. Here, the constant current source 2411, the constant current source 2417, the amplifier 2412, the monitoring element 2427 and the monitoring element 2429 are connected directly, however, other elements such as a resistor and a switch may be interposed therebetween.

### Embodiment 5

In Embodiments 1 to 4, the first power source terminal and the second power source terminal of the display panel are fixed, however, a change-over switch for regularly switching a voltage applied to these terminals may be interposed so as to alternately drive the light emitting element and the monitoring element.

Description has been made in Embodiments 1 to 4 on the temperature compensation, however, compensation can also be made for the degradation of the light emitting element by utilizing the similar degradation of the monitoring element and the light emitting element.

### Embodiment 6

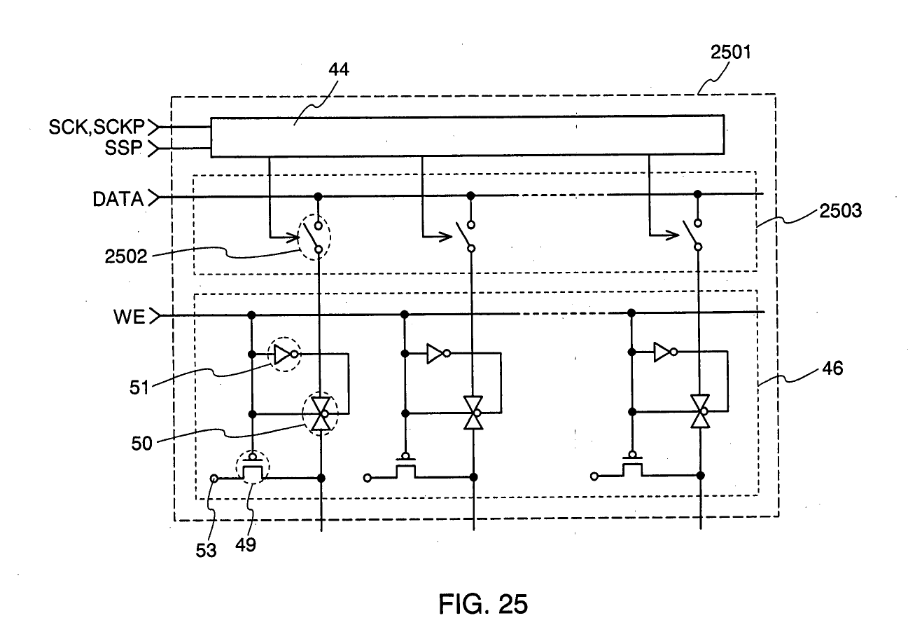

The invention is not limited to the source driver 43 of a line-sequential drive operation as shown in FIG. 4, and can be applied to a source driver of a dot-sequential drive operation. Hereupon, description is made in this embodiment with reference to FIG. 25 on an exemplary source driver of a dot-sequential drive operation that is applicable to the display device of the invention. Note that common portions to those in the source driver 43 in FIG. 4 are denoted by common reference numerals.

A source driver 2501 in FIG. 25 includes the pulse output circuit 44, a switch group 2503 and the selection circuit 46. The switch group includes a switch 2502 corresponding to each column of pixels. The selection circuit 46 also includes the inverter 51, the analog switch 50 and the TFT 49 corresponding to each column of pixels. One terminal of the TFT 49 is connected to the power source 53. The pulse output circuit 44 may be, for example, a shift register.

Description is made briefly on the operating method of the source driver 2501.

When the source driver 2501 performs a writing operation, a WE signal at H level is supplied and the analog switch 50 is turned ON. At this time, the TFT 49 for transmitting an erasing signal is turned OFF. The switch 2502 on the column to be written with a DATA signal is sequentially selected by the pulse output circuit 44, thereby a DATA signal is written to a pixel.

When the source driver 2501 performs an erasing operation, a WE signal at L level is supplied, the analog switch 50 is turned OFF and the erasing TFT 49 is turned ON. One terminal of the erasing TFT 49 is connected to the power source 53, thereby a potential of the power source 53 can be set at the potential of the signal line, therefore, a gate potential of a TFT for driving the pixel can be set. That is, there is no more potential difference between the gate and the source of the TFT for driving the pixel, thus a charge accumulated in the storage capacitor for storing the gate-source voltage can be released. The TFT for driving the pixel corresponds to the TFT 12, the signal line corresponds to the S1 to Sm, and the storage capacitor corresponds to the capacitor 16 in FIG. 4. The source potential of the TFT 12 is a potential of the power source line Vx. That is, the potential of the power source 53 and the potential of the power source line Vx are desirably set equal. In this manner, a signal written by the source driver can be erased.

### Embodiment 7

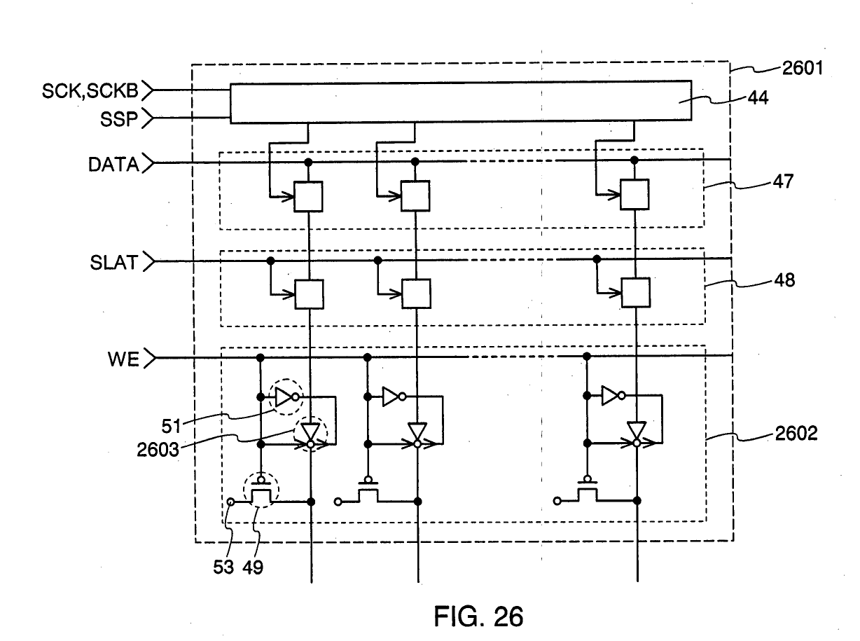

In this embodiment, description is made with reference to FIG. 26 on another configuration of the selection circuit 46 included in the source driver 43. In the configuration of this embodiment, a clocked inverter 2603 is used in place of the analog switch 50 that is used in the selection circuit 46 of the source driver 43 shown in FIG. 4. Note that common portions to those in the source driver 43 in FIG. 4 are denoted by common reference numerals.

A source driver 2601 shown in this embodiment includes the pulse output circuit 44, the first latch 47, the second latch 48 and a selection circuit 2602. The selection circuit 2602 includes the inverter 51, a clocked inverter 2603 and the TFT 49. One terminal of the TFT 49 is connected to the power source 53.

Description is made in brief on the operating method of the selection circuit 2602.

When the source driver 2601 performs a writing operation, a WE signal at H level is supplied, thereby a signal inputted to the clocked inverter 2603 can be outputted. At this time, the TFT 49 for transmitting an erasing signal is turned OFF. In this manner, a signal from the second latch 48 can be written to the pixel.

When the source driver performs an erasing operation, a WE signal at L level is supplied, thereby a signal inputted to the clocked inverter 2603 is not outputted. In addition, the TFT 49 is turned ON. In this manner, the signal lines S1 to Sm can be set at the potentials of the power source 53, and the signal written in the pixel can be erased.

Note that the selection circuit 2602 shown in this embodiment can be applied to the source driver 2501 shown in FIG. 25 in Embodiment 6.

### Embodiment 8

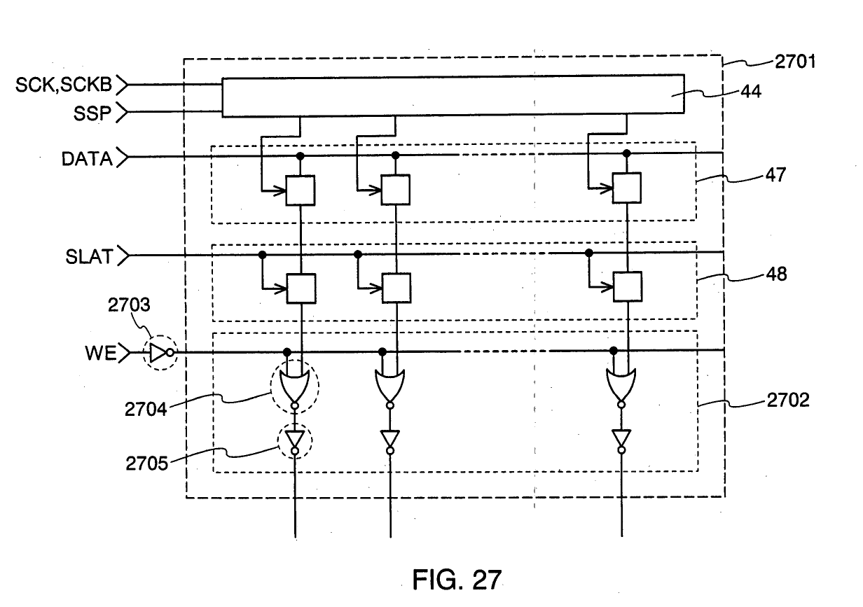

When digital signals are supplied, each circuit can be shown by a logic gate. In this embodiment, description is made with reference to FIG. 27 on the example where the selection circuit 46 in the source driver 43 is shown by logic gate circuits. Note that common portions to those in the source driver 43 in FIG. 4 are denoted by common reference numerals.

A source driver 2701 includes the pulse output circuit 44, the first latch 47, the second latch 48 and a selection circuit 2702. The selection circuit 2702 includes a NOR gate 2704 and an inverter 2705. Note that one terminal of the NOR gate 2704 in each column of the selection circuit 2702 is inputted with the WE signal inverted by the inverter 2703. When the source driver performs a writing operation, a WE signal at H level is supplied. Then, the signal is inverted by the inverter 2703, thereby the L-level signal is inputted to one of the input terminals of the NOR gate 2704 in each column. The other input terminal thereof is inputted with a signal from the second latch 48 of each column. When an H-level signal is supplied from the second latch 48, an output of the NOR gate is at L level, which is then inverted by the inverter 2705, thereby an H-level signal is outputted to the source line. Thus, the gate potential of the TFT 12 in the pixel selected by a gate line is at H level, thereby the TFT 12 is turned ON. When an L-level signal is supplied from the second latch 48, an output of the NOR gate 2704 is at H level, which is then inverted by the inverter 2705, thereby an L-level signal is outputted to the source line. Thus, the gate potential of the TFT 12 in the pixel selected by a gate line is at L level, thereby the TFT 12 is turned OFF. These potentials are accumulated in the capacitor 16. In this manner, signals can be written to pixels.

In the erasing operation, a WE signal at L level is supplied. Then, it is inverted by the inverter 2703, thereby an H-level signal is inputted to one of the input terminals of the NOR gate 2704 in each column. Then, the output of the NOR gate is at L level regardless of the signal from the second latch 48 (that is, an input signal to the other input terminal of the NOR gate), which is then inverted by the inverter 2705, thereby an H-level signal is outputted to a source line. The gate potential of the TFT 12 in the pixel selected by a gate line is at H level, thereby the capacitor 16 is discharged and the TFT 12 is turned OFF. In this manner, signals written in pixels can be erased.

Note that the selection circuit 2702 shown in this embodiment can be applied to the source driver 2501 shown in FIG. 25 of Embodiment 6.

### Embodiment 9

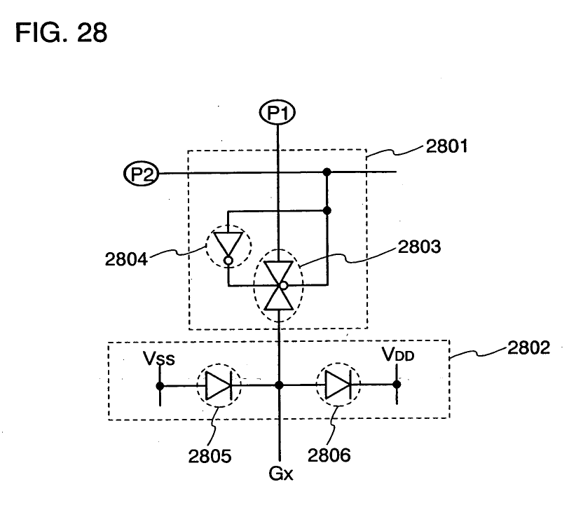

In this embodiment, description is made with reference to FIG. 28 on the example where the tristate buffer 87 and the protection circuit 88 of the selection circuit 55 included in the first gate driver 41 shown in FIG. 4 has a different configuration. The tristate buffer 87 shown in FIG. 9 functions to prevent that when one of the first gate driver 41 and the second gate driver 42 charges or discharges the gate line Gy, the operation is disturbed by the output of the other driver. Accordingly, the tristate buffer 87 may be, as long as having the above function, an enable circuit 2801 using an analog switch 2803 as shown in FIG. 28. A protection circuit 2802 includes rectifiers 2805 and 2806.

The enable circuit 2801 includes the analog switch 2803 and an inverter 2804. The analog switch 2803 is turned ON/OFF by a P2 signal, thereby a P1 signal is transmitted to a gate line. That is, in order to prevent that when one of the first gate driver 41 and the second gate driver 42 charges or discharges the gate line Gy, the operation is disturbed by the output of the other driver, P2 signals to be inputted to the enable circuit 2801 in each of the first gate driver 41 and the second gate driver 42 are required to be inverted from each other.

The first gate driver 41 includes the first protection circuit (corresponds to the resistor 72 in the drawing) connected to the input node of the pulse output circuit 54, and the second protection circuit 2802 provided on the lower stage of the selection circuit 46. According to such a configuration, degradation or breakdown of elements caused by static electricity can be suppressed. More specifically, there is a possibility that a clock signal or a data signal inputted to the input node has noise, which may cause a high voltage or a low voltage to be instantaneously applied to elements. However, according to the invention having a protection circuit, malfunction, degradation or breakdown of elements can be suppressed.

Note that the protection circuit is constructed by using not only a resistor and a transistor, but one or more elements selected from a resistor, a capacitor and a rectifier. The rectifier is a transistor whose gate electrode and drain electrode are connected to each other, or a diode. In this embodiment, the rectifiers 2805 and 2806 are applied to the protection circuit 2802, however, one or more elements selected from a resistor, a capacitor and a rectifier may be adopted. Note that the rectifier may be a PN junction diode, a PIN junction diode, a Shottoky diode, and the like other than the diode-connected transistor.

Description is made now on the operation of a protection circuit. Here, description is made on the operation of the protection circuit 2802 included in the first gate driver 41.

First, when a signal of a higher voltage than VDD is supplied from the output node of the enable circuit 2801 due to an effect of noise and the like, a forward bias is applied to the rectifier 2806, and a charge stored in the enable circuit 2801 is released to the power source line for transmitting VDD, thereby a potential of the gate line Gx becomes VDD or VDD+a.

On the other hand, when a signal of a voltage lower than VSS is supplied from the output node of the enable circuit 2801, a forward bias is applied to the rectifier 2805, thereby the potential of the gate line Gx becomes VSS or VSS−a.

In this manner, even when a voltage supplied from the output node of the enable circuit 2801 becomes higher than VDD or lower than VSS instantaneously due to noise and the like, the voltage supplied to the gate line Gx does not become higher than the VDD nor lower than VSS.

Accordingly, malfunction, degradation or breakdown of elements caused by noise, static electricity and the like can be suppressed.

### Embodiment 10

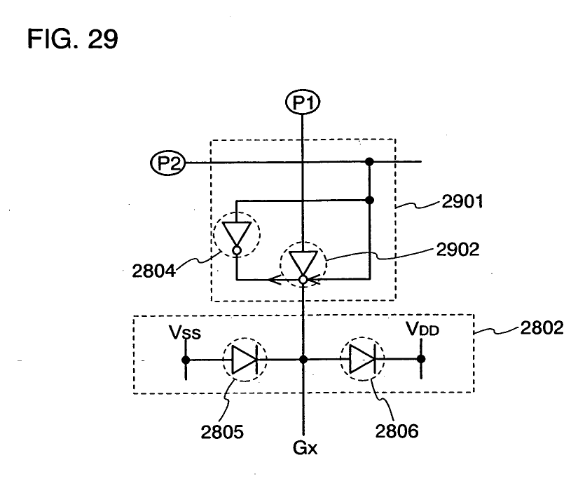

In this embodiment, description is made with reference to FIG. 28 on the example where the tristate buffer 87 and the protection circuit 88 of the selection circuit 55 included in the first gate driver 41 shown in FIG. 4 has a different configuration. The tristate buffer 87 shown in FIG. 9 functions to prevent that when one of the first gate driver 41 and the second gate driver 42 charges or discharges the gate line Gy, the operation is disturbed by the output of the other driver. Accordingly, the tristate buffer 87 may be, as long as the above function is provided, an enable circuit 2901 using a clocked inverter 2902 as shown in FIG. 29. The protection circuit 2802 includes the rectifiers 2805 and 2806. Note that this configuration is the one where a clocked inverter is employed in place of the analog switch included in the enable circuit 2801, and the operating method thereof is omitted as it is similar to those of the enable circuit 2801 and the protection circuit 2802 shown in FIG. 28 in Embodiment 9.

### Embodiment 11

In this embodiment, description is made on the selection signal line 52 shown in FIG. 4 and the like. A WE signal is inputted to the gate driver or the source driver through the selection signal line 52. At this time, actual input timing of signals to pixels has to be considered.

That is, it is necessary to consider a timing at which selection of a gate line is canceled, and a timing at which a video signal or an erasing signal transmitted from a source line to a pixel changes. For example, if a video signal or an erasing signal changes before a selected gate line is canceled, the changed signal is inputted to the pixel. Thus, it is essential to keep the video signal or the erasing signal to be inputted to the pixel unchanged until the selected gate line is canceled. After the selected gate line is canceled, the video signal or the erasing signal may be changed.

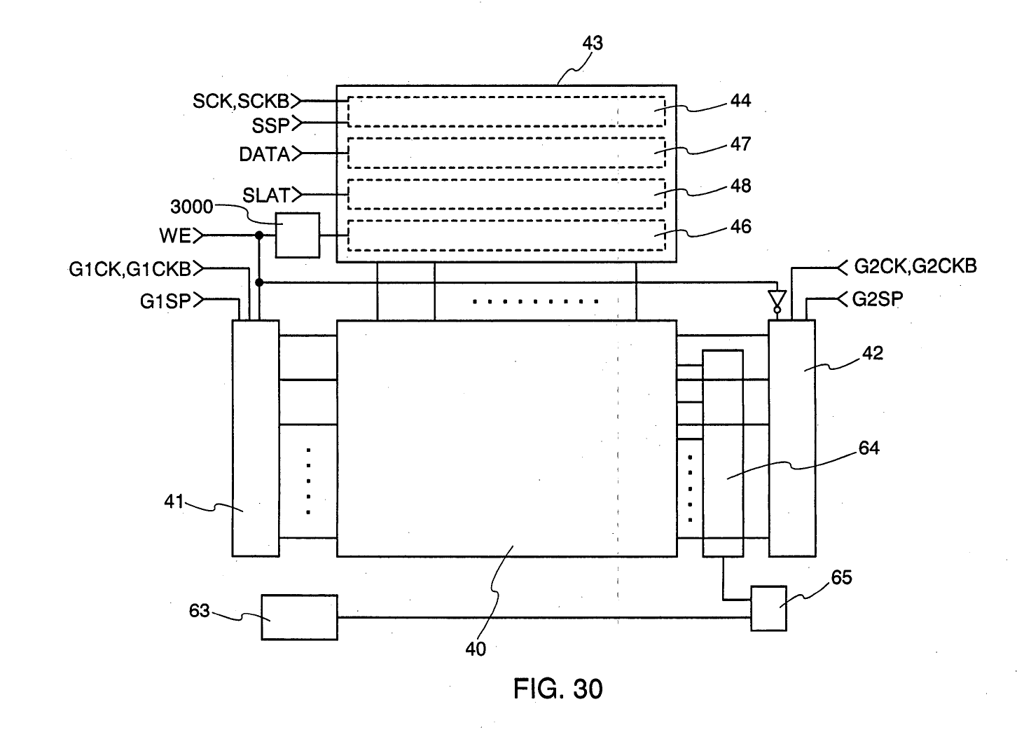

Then, as shown in FIG. 30, a delay circuit 3000 may be provided before the input of a WE signal to the source driver 43. The WE signal may be directly inputted to the gate driver. As a result, upon the change of the WE signal, the WE signal is inputted to the source driver with a delay by the delay circuit. Thus, a timing at which the video signal or the erasing signal changes can be delayed than the timing at which a selected gate line is canceled. As a result, accurate signals can be inputted to the pixel. Note that FIG. 30 is a schematic diagram where common portions to those in FIG. 4 are denoted by common reference numerals.

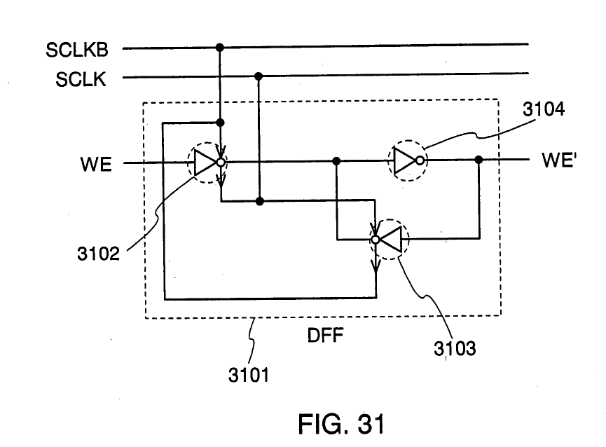

FIG. 31 illustrates an example of a delay circuit. Basically, inputted signals may be outputted after being delayed. FIG. 31 is an example of adopting a flip-flop circuit. A flip-flop circuit 3101 as shown in FIG. 31 includes a clocked inverter 3102, a clocked inverter 3103 and an inverter 3104, which is generally called a delay flip-flop circuit (DFF). The clocked inverters 3102 and 3103 constituting the DFF operate in synchronization with the input of the clock signals. Therefore, when one stage of DFFs is disposed as a delay circuit, a signal is delayed by half cycle of a clock signal supplied to the DFFs.

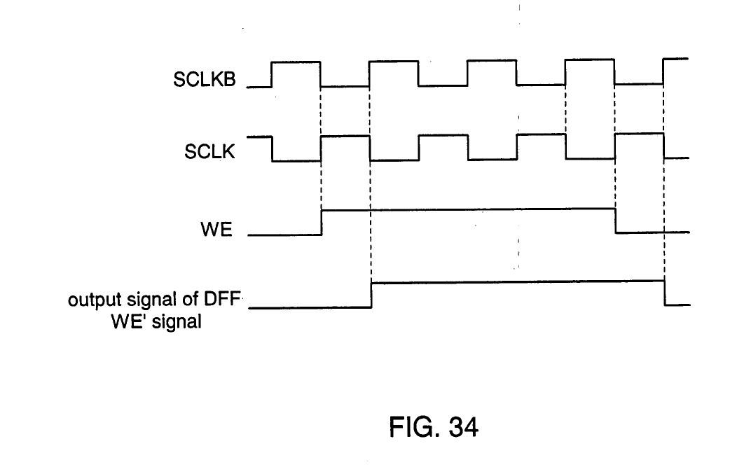

FIG. 34 is a timing chart. It is apparent that an output signal of the DFF 3101 (WE′ signal) is delayed by a half cycle of a clock signal as compared to an input signal of the DEE 3101 (WE signal).

Here, clock signals inputted to the DFF 3103 of the delay circuit may be any signals. However, if there is an available signal among those inputted for other purposes, such a signal can be effectively utilized for the clock signal. Thus, a clock signal inputted to the source driver is desirably employed.

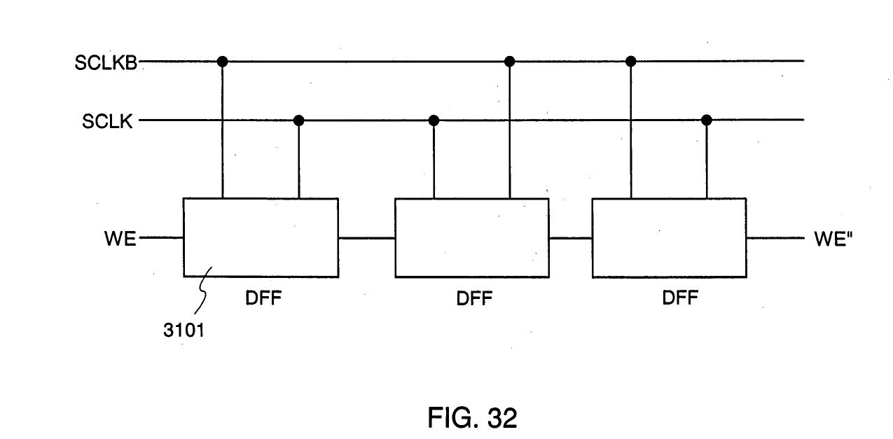

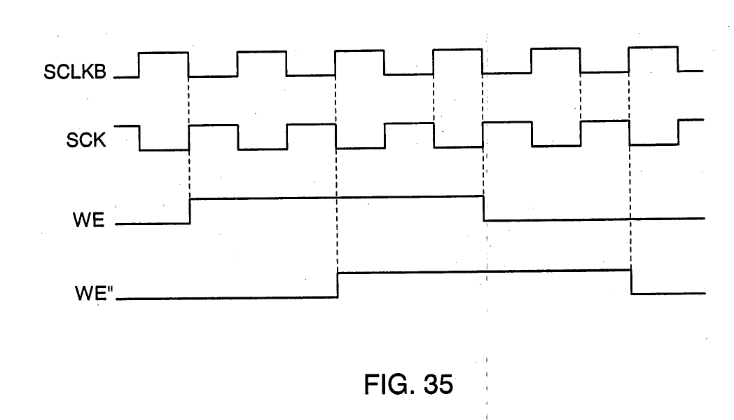

In the case of FIG. 31, a signal is delayed by a half cycle of a clock signal inputted to the DFF 3103. If the signal is required to be delayed more, a plurality of the DFFs 3101 may be connected in series as shown in FIG. 32. By controlling the number of stages of the DFFs 3101, delay time can be arbitrarily determined. In FIG. 32, three stages of the DFFs are connected in series. Thus, it is apparent from a timing chart in FIG. 35 that an output signal of the DFF (WE″ signal) is delayed three times as long as a half cycle of the clock signal as compared to an input signal of the DFF (WE signal).

Note that FIGS. 31 and 32 show the configurations employing the DFF, however, the invention is not limited to this. Any other circuit having a configuration applicable to a shift register can be used.

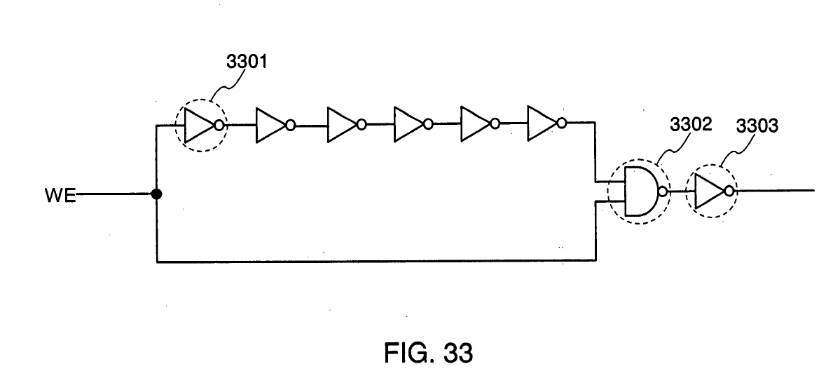

Alternatively, signals may be delayed not by using the synchronization with clock signals but by utilizing a delay time that occurs by serial propagation of signals from a plurality of circuits. FIG. 33 illustrates a configuration of such a case. Here, signals are delayed by connecting a plurality of stages of inverters 3301. When necessary, a NAND 3302 may be provided to receive signals of both before and after being delayed in order to narrow the pulse width of signals. The inverted signal is inverted again in an inverter 3303.

### Embodiment 12

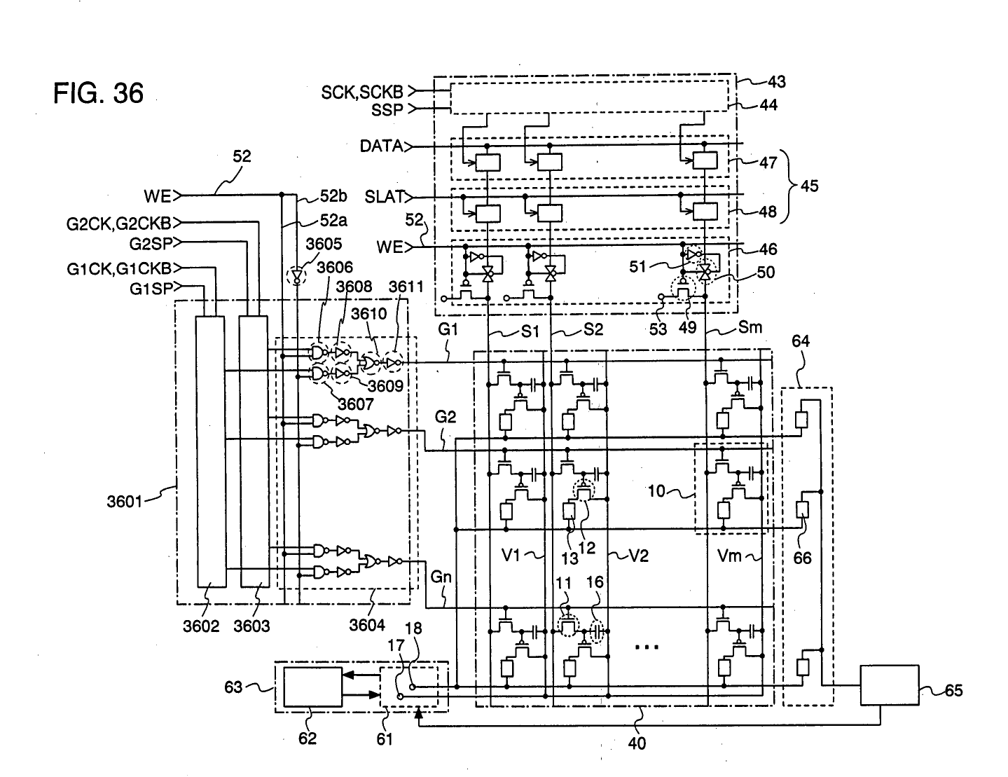

The display device shown in FIG. 4 has a configuration where the first gate driver 41 and the second gate driver 42 are disposed on opposite sides of the pixel region 40. On the other hand, FIG. 36 illustrates a display device that operates similarly to the display device having the configuration in FIG. 4, but has a configuration where one gate driver is disposed on one side. Note that common portions to those in the display device shown in FIG. 4 are denoted by common reference numerals.

The source driver 43 includes the pulse output circuit 44, the latch 45 and the selection circuit 46. The latch 45 includes the first latch 47 and the second latch 48. The selection circuit 46 includes the TFT 49 and the analog switch 50. The TFT 49 and the analog switch 50 are provided in each column correspondingly to the source line Sx. The inverter 51 generates an inverted signal of a WE (Write/Erase) signal, and it is not necessarily provided when the inverted signal of the WE signal is supplied externally.

The gate electrode of the TFT 49 is connected to the selection signal line 52, and one of the source electrode and the drain electrode thereof is connected to the source line Sx while the other thereof is connected to the power source 53. The analog switch 50 is provided between the second latch 48 and the source line Sx. That is, an input node of the analog switch 50 is connected to the second latch 48 while an output node thereof is connected to the source line Sx. One of the two control nodes of the analog switch 50 is connected to the selection signal line 52 while the other thereof is connected to the selection signal line 52 through the inverter 51. A potential of the power source 53 has a level to turn OFF the TFr 12 included in the pixel 10. When the TFT 12 is an N-channel TFT, the potential of the power source 53 is set at L level and when the TFT 12 is a P-channel TFT, on the other hand, the potential of the power source 53 is set at H level.

A gate driver 3601 includes a first pulse output circuit 3603, a second pulse output circuit 3602 and a selection circuit 3604. The selection circuit 3604 includes NAND gates 3606 and 3607, inverters 3608, 3609 and 3611, and a NOR gate 3610 correspondingly to each column. The selection signal line 52 is branched, and one of them (selection signal line 52a) is connected to one terminal of the NAND gate 3606. The other terminal of the NAND gate 3606 is connected to the first pulse output circuit 3603. The other of the branched selection signal line 52 (selection signal line 52b) is connected to one terminal of the NAND gate 3607. The other terminal of the NAND gate 3607 is connected to the second pulse output circuit 3602. The output terminal of the NAND gate 3606 is connected to the input terminal of the inverter 3608, and the output terminal of the NAND gate 3607 is connected to the input terminal of the inverter 3609. The output terminals of the inverters 3608 and 3609 are connected to the input terminals of the NOR gate 3610 respectively, and the output terminal of the NOR gate 3610 is connected to the input terminal of the inverter 3611. That is, a signal inputted from the selection signal line 52a to the selection circuit 3604 and a signal inputted from the selection signal line 52b to the selection circuit 3604 are inverted from each other.

Description is made now on the operating method of the gate driver of this embodiment.

When both of the input terminals of the NAND gate 3606 and the NAND gate 3607 become H level, an H-level signal is inputted to the gate line Gx.

When writing a signal to a pixel, a WE signal at H level is inputted. Then, the H-level signal is inputted to one terminal of the NAND gate 3606 from the selection signal line 52a. Accordingly, the row of the gate line to which the H-level signal is outputted from the first pulse output circuit 3603 that is connected to the other terminal of the NAND gate 3606 corresponds to the pixel row that is selected for writing signals. That is, the transistor 11 in the pixel of the row for writing signals is turned ON. When a WE signal at H level is supplied, the analog switch in the selection circuit 46 is turned ON, thereby a signal from the second latch 48 is outputted to the signal line Sx. Accordingly, a charge is accumulated in the capacitor 16 for storing a gate potential of the TFT 12 for driving the pixel, thereby a signal can be written to the pixel.

In the erasing operation for erasing a signal written in the pixel, a WE signal at L level is supplied. Then, an H-level signal is inputted to one terminal of the NAND gate 3607 through the inverter 3605 from the selection signal line 52b. Accordingly, the row of the gate line to which the H-level signal is outputted from the second pulse output circuit 3602 that is connected to the other terminal of the NAND gate 3607 corresponds to the pixel row that is selected for erasing signals. That is, the transistor 11 in the pixel of the row for erasing signals is turned ON. When a WE signal at L level is supplied, the TFT 49 in the selection circuit 46 is turned ON, thereby a potential of the power source 53 is at the potential of the signal line Sx. Accordingly, a charge accumulated in the capacitor 16 for storing a gate potential of the TFT 12 for driving the pixel is released, thereby a signal written in the pixel can be erased.

The pulse output circuit 44 included in the source driver 43, the first pulse output circuit 3603 and the second pulse output circuit 3602 included in the gate driver 3601 correspond to a shift register having a plurality of flip-flop circuits, or a decoder circuit. When adopting a decoder circuit for each of the pulse output circuits 44, 3602 and 3603, the source line Sx or the gate line Gy can be selected at random. When the source line Sx or the gate line Gy can be selected at random, pseudo contours that occur when adopting a time gray scale method can be suppressed.

Note that the configuration of the source driver 43 is not limited to the above, and a level shifter and a buffer may be provided additionally. In addition, the configuration of the gate driver 3601 is not limited to the above, and a level shifter and a buffer may be provided additionally. Further, though not shown, each of the source driver 43 and the first gate driver 3601 includes a protection circuit. The configuration of the driver including a protection circuit may be the one described in Embodiment Mode 3.

Note that the delay circuits shown in FIGS. 31 to 33 in Embodiment Mode 11 can be applied to the display device shown in FIG. 36 of this embodiment.

In addition, the display device of the invention includes a power source control circuit 63. The power source control circuit 63 includes the power source circuit 61 for supplying power to the light emitting element 13, and the controller 62. The power source circuit 61 is connected to the pixel electrode of the light emitting element 13 through the TFT 12 and the power source line Vx. Also, the power source circuit 61 is connected to the counter electrode of the light emitting element 13 through the power source line.

When a forward bias voltage is applied to the light emitting element 13 so as to supply a current to the light emitting element 13 to emit light, the first power source 17 and the second power source 18 are set to have a potential difference so that the potential of the first power source 17 is higher than the potential of the second power source 18. On the other hand, when a reverse bias voltage is applied to the light emitting element 13, the first power source 17 and the second power source 18 are set to have a potential difference so that the potential of the first power source 17 is lower than the potential of the second power source 18. Such potential setting is performed by supplying a predetermined signal from the controller 62 to the power source circuit 61.

According to the invention, a reverse bias voltage is applied to the light emitting element 13 using the power source control circuit 63, whereby degradation of the light emitting element 13 with the passage of time can be suppressed to improve the reliability. The light emitting element 13 may have an initial defect that the anode and the cathode thereof are short-circuited due to adhesion of foreign substances, pinholes that are produced by minute projections of the anode or the cathode, or irregularity of the electroluminescent layer. Such an initial defect disturbs emission/non-emission in accordance with signals, and a problem will arise where a favorable image display cannot be performed because the whole elements do not emit light with almost all currents flown to the short-circuit portion, or specific pixels emit light or no light. However, according to the structure of the invention, a reverse bias can be applied to the light emitting element, whereby a current can locally flow only to the short-circuit portion of the anode and the cathode so as to generate heat in the short-circuit portion. As a result, the short-circuit portion can be insulated by oxidization or carbonization. Thus, even when an initial defect occurs, favorable image display can be performed by eliminating the defect. Note that insulation of such an initial defect is preferably carried out before shipment. Further, not only an initial defect, but another defect might occur where the anode and the cathode are short-circuited with the passage of time. Such a defect is called a progressive defect. However, according to the invention, a reverse bias can be applied to the light emitting element at regular intervals, therefore, such possible progressive defect can be eliminated to perform favorable image display. Note that the timing for applying a reverse bias voltage to the light emitting element 13 is not specifically limited.

The display device of the invention also includes a monitoring circuit 64 and a control circuit 65. The monitoring circuit 64 operates in accordance with the ambient temperature. The control circuit 65 includes a constant current source and a buffer. In the shown configuration, the monitoring circuit 64 includes a monitoring light emitting element 66.

The control circuit 65 supplies a signal for changing a power source potential to the power source control circuit 63 based on the output of the monitoring circuit 64. The power source control circuit 63 changes a power source potential to be supplied to the pixel region 40 based on the signal supplied from the control circuit 65. According to the invention having the above configuration, fluctuations of a current value caused by changes in the ambient temperature can be suppressed to improve the reliability. Note that each of the monitoring circuit 64 and the control circuit 65 may have the configuration described in Embodiment Mode 3.

According to the display device of the invention that performs a constant voltage drive, luminance of the light emitting elements is 500 cd/m², and power consumption is 1 W or less (950 mW) with the pixel aperture ratio 50%. On the other hand, according to a display device that performs a constant current drive, luminance of the light emitting elements is 500 cd/m², and power consumption is 2 W (2040 mW) with the pixel aperture ratio of 25%. That is, by adopting a constant voltage drive, power consumption can be reduced. By adopting a constant voltage drive, power consumption can be suppressed to 1 W or less, or more preferably to 0.7 W or less. Note that the above value of the power consumption is only of the pixel region, and does not include the power consumption of the driver circuit portions. In addition, both exhibits a display duty ratio of 70% with the time gray scale method adopted.

In addition, the number of the pixels in the pixel region is 240×3×320 in both of the display device for performing a constant voltage drive and the display device for performing a constant current drive of which power consumption were measured as set forth above.

1. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, a second transistor for controlling emission/non-emission of the light emitting element, and a capacitor for storing a video signal,
wherein a gate electrode of the first transistor is operationally connected to both of the first gate driver and the second gate driver.

2. The display device according to claim 1 wherein a conductive layer connected to one of source electrodes and drain electrodes of the first transistor and the second transistor has a thickness of 500 to 1300 nm.

3. The display device according to claim 1 further comprising:
a first insulating layer provided over the first transistor and the second transistor; and
a second insulating layer over the first insulating layer,
wherein a first electrode of the light emitting element is provided on the second insulating layer.

4. The display device according to claim 1 further comprising an insulating layer covering an edge of a first electrode of the light emitting element,
wherein the insulating layer located above the capacitor has a width of 10 to 25 μm in a column direction.

5. The display device according to claim 1 further comprising an insulating layer covering an edge of a first electrode of the light emitting element,
wherein the insulating layer is a light blocking layer.

6. The display device according to claim 1 wherein one of a first electrode and a second electrode of the light emitting element reflects light while the other transmits light.

7. The display device according to claim 1 wherein both of a first electrode and a second electrode of the light emitting element transmit light.

8. The display device according to claim 1 wherein a power source control circuit is provided for changing potentials of a first power source and a second power source so that a reverse bias can be applied to the light emitting element.

9. The display device according to claim 1 wherein the light emitting element includes a material for red emission that is obtained from a triplet excitation state, a material for green emission that is obtained from a singlet excitation state, or a material for blue emission that is obtained from a singlet excitation state.

10. The display device according to claim 1 wherein the light emitting element is formed of a material for red emission that is obtained from a triplet excitation state, a material for green emission that is obtained from a triplet excitation state, or a material for blue emission that is obtained from a singlet excitation state.

11. The display device according to claim 1 wherein a plurality of power source lines connected to a first power source are provided in columns, and each power source line is shared by adjacent pixels.

12. The display device according to claim 1 wherein a protection circuit is provided between the source driver and a connecting film and the protection circuit is one or more elements selected from a resistor, a capacitor and a rectifier.

13. The display device according to claim 1 wherein a monitoring circuit is provided as well as a control circuit for changing a power source potential to be supplied to the pixel region based on the output of the monitoring circuit; and
wherein the control circuit is a switching regulator.

14. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, a second transistor for controlling emission/non-emission of the light emitting element, and a capacitor for storing a video signal;
wherein a gate electrode of the first transistor is operationally connected both of the first gate driver and the second gate driver;
wherein the source driver includes a first selection circuit for selecting a signal output operation for writing to the pixel, or a signal output operation for erasing the signal written in the pixel;
wherein each of the first gate driver and the second gate driver includes a second selection circuit for selecting either operation of the first gate driver or the second gate driver; and
wherein a delay circuit is provided for delaying an input signal of the second selection circuit for selecting either operation of the first gate driver or the second gate driver so as to be outputted to the first selection circuit.

15. The display device according to claim 14, wherein the delay circuit includes a plurality of flip-flop circuits.

16. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, a second transistor for controlling emission/non-emission of the light emitting element, and a capacitor for storing a video signal;
wherein a gate electrode of the first transistor is operationally connected both of the first gate driver and the second gate driver; and
wherein the capacitor includes a second semiconductor layer provided in the same layer as a first semiconductor layers of the first transistor and the second transistor, a conductive layer provided in the same layer as gate electrodes of the first transistor and the second transistor, and an insulating layer provided between the second semiconductor layer and the conductive layer.

17. A display device comprising:
a pixel region including a plurality of pixels;
a source driver;
a first gate driver; and
a second driver,
wherein each of the plurality of pixels includes a light emitting element, a first transistor for controlling a video signal input to the pixel, a second transistor for controlling emission/non-emission of the light emitting element, and a capacitor for storing a video signal;
wherein a gate electrode of the first transistor is operationally connected both of the first gate driver and the second gate driver; and
wherein the capacitor includes a first conductive layer provided in the same layer as gate electrodes of the first transistor and the second transistor, a second conductive layer provided in the same layer as conductive layers connected to source electrodes and drain electrodes of the first transistor and the second transistor, and an insulating layer provided between the first conductive layer and the second conductive layer.

18. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, a second transistor for controlling emission/non-emission of the light emitting element;
wherein a gate electrode of the first transistor is operationally connected both of the first gate driver and the second gate driver; and
wherein a monitoring circuit is provided as well as a power source control circuit for changing a power source potential to be supplied to the pixel region based on an output of the monitoring circuit.

19. The display device according to claim 18 wherein the monitoring circuit includes a monitoring light emitting element.

20. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, and a second transistor for controlling emission/non-emission of the light emitting element;
wherein a gate electrode of the first transistor is operationally connected both of the first gate driver and the second gate driver;
wherein the source driver includes a pulse output circuit, a latch, a selection circuit, a first protection circuit connected to an input node of the pulse output circuit, a second protection circuit provided between the pulse output circuit and the latch, and a third protection circuit provided between the selection circuit and the pixel region; and
wherein each of the first to third protection circuits is one or more elements selected from a resistor, a capacitor and a rectifier.

21. A display device comprising:
a pixel region including a plurality of pixels;
a source driver;
a first gate driver; and
a second gate driver,
wherein each of the plurality of pixels includes a light emitting element, a first transistor for controlling a video signal input to the pixel, and a second transistor for controlling emission/non-emission of the light emitting element;
wherein a gate electrode of the first transistor is operationally connected both of the first gate driver and the second gate driver;
wherein each of the first gate driver and the second driver includes a pulse output circuit, a selection circuit, a first protection circuit connected to an input node of the pulse output circuit, and a second protection circuit provided between the selection circuit and the pixel region; and
wherein each of the first protection circuit and the second protection circuit is one or more elements selected from a resistor, a capacitor and a rectifier.

22. The display device according claim 20, wherein the rectifier includes a transistor whose gate electrode and drain electrode are connected to each other, or a diode.

23. The display device according claim 21, wherein the rectifier includes a transistor whose gate electrode and drain electrode are connected to each other, or a diode.

24. The display device according to claim 20, wherein the pulse output circuit corresponds to a plurality of flip-flop circuits or a decoder circuit.

25. The display device according to claim 21, wherein the pulse output circuit corresponds to a plurality of flip-flop circuits or a decoder circuit.

26. The display device according to claim 1,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

27. The display device according to claim 14,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

28. The display device according to claim 16,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

29. The display device according to claim 17,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

30. The display device according to claim 18,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

31. The display device according to claim 20,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

32. The display device according to claim 21,
wherein one of a source electrode and a drain electrode of the first transistor is connected to the source driver through a source line;
wherein the other of the source electrode and the drain electrode of the first transistor is connected to the gate electrode of the second transistor;
wherein one of a source electrode and a drain electrode of the second transistor is connected to a pixel electrode of the light emitting element; and
wherein the other of the source electrode and the drain electrode of the second transistor is connected to a power source.

33. An electronic appliance having the display device according to claim 1.

34. A light emitting display device comprising:
a source driver;
a first gate driver;
a second gate driver;
a pixel;
a source line for supplying signals to said pixel from said source driver; and
a gate line electrically connected to the first and second gate drivers,
said pixel including:
a first transistor wherein a gate electrode of the first transistor is operationally connected to said first gate driver and said second gate driver through the gate line and one of a source or a drain of the first transistor is electrically connected to the source line;
a second transistor wherein a gate electrode of the second transistor is electrically connected to the source line through the first transistor;
wherein said source driver supplies a video signal to said pixel during a first selection period of the first transistor in which the first transistor is selected by the first gate driver, and said source driver supplies an erasing signal to said pixel during a second selection period in which the first transistor is selected by the second gate driver.

35. The display device according to claim 34 wherein the first period occurs after the second period in one sub-frame.

36. The display device according to claim 34 wherein the second period occurs after the first period in one sub-frame.

37. The display device according to claim 34 wherein said pixel is located between the first and second gate drivers.
